(19) United States
(12) Patent Application Publication
(10) Pub. No.: US 2024/0088218 A1
(43) Pub. Date: Mar. 14, 2024

(54) GATE CUTS IN A GRATING PATTERN ACROSS AN INTEGRATED CIRCUIT

(71) Applicant: Intel Corporation, Santa Clara, CA (US)

(72) Inventors: Shao-Ming Koh, Tigard, OR (US); Leonard P. Guler, Hillsboro, OR (US); Gurpreet Singh, Beaverton, OR (US); Manish Chandhok, Beaverton, OR (US); Matthew J. Prince, Portland, OR (US)

(73) Assignee: Intel Corporation, Santa Clara, CA (US)

(21) Appl. No.: 17/943,443

(22) Filed: Sep. 13, 2022

(51) Int. Cl. H01L 29/06; H01L 21/8234; H01L 27/088; H01L 29/08; H01L 29/778; H01L 29/786

(52) U.S. Cl. CPC H01L 29/0673; H01L 21/823412; H01L 21/823418; H01L 27/0886; H01L 29/0847; H01L 29/778; H01L 29/78696

(57) ABSTRACT

Techniques are provided herein to form an integrated circuit having a grating pattern of gate cut structures such that a gate cut structure extends between the gate layers of adjacent semiconductor devices and between the source or drain regions (e.g., epitaxial regions) of the adjacent semiconductor devices. In an example, neighboring semiconductor devices each include a semiconductor region extending between a source region and a drain region, and a gate structure extending over the semiconductor regions of the neighboring semiconductor devices. In some such examples, a gate cut structure is present between each pair of neighboring semiconductor devices thus interrupting the gate structure and isolating the gate electrode of one semiconductor device from the gate electrode of the other semiconductor device. The gate cut structure further extends to separate the source or drain regions of the neighboring semiconductor devices. Subsequent processes allow neighboring gate or source or drain regions connections.

### FIELD OF THE DISCLOSURE

The present disclosure relates to integrated circuits, and more particularly, to gate cut structures.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Certain aspects of lithography technology can impose physical limits on how accurately certain structures can be aligned. Due to the high complexity of integrated circuit layouts, any structures that require additional masking processes or tight alignment tolerances give rise to reduced yield, or possible points of failure for the device. Accordingly, there remain a number of non-trivial challenges with respect to forming such high-density semiconductor devices.

### BRIEF DESCRIPTION OF THE DRAWINGS

FIG. 1A is an isometric view of an integrated circuit structure that includes gate cut structures in a grating pattern and metal gate bridges, in accordance with an embodiment of the present disclosure.

FIG. 1B is a plan view of an integrated circuit that includes a grating pattern of gate cut structures between adjacent devices, in accordance with an embodiment of the present disclosure.

FIGS. 1C and 1D are different cross-sectional views of the integrated circuit of FIG. 1B that show the gate cut structures passing between adjacent gate structures (1C) and between adjacent source or drain regions (1D), in accordance with an embodiment of the present disclosure.

FIGS. 2A-2C are plan and cross-sectional views, that illustrate one stage in an example process for forming an integrated circuit configured with gate cut structures in a grating pattern, in accordance with an embodiment of the present disclosure.

FIGS. 3A-3C are plan and cross-sectional views, that illustrate another stage in the example process for forming the integrated circuit configured with gate cut structures in a grating pattern, in accordance with an embodiment of the present disclosure.

FIGS. 4A-4C are plan and cross-sectional views, that illustrate another stage in the example process for forming the integrated circuit configured with gate cut structures in a grating pattern, in accordance with an embodiment of the present disclosure.

FIGS. 5A-5C are plan and cross-sectional views, that illustrate another stage in the example process for forming the integrated circuit configured with gate cut structures in a grating pattern, in accordance with an embodiment of the present disclosure.

FIGS. 6A-6C are plan and cross-sectional views, that illustrate another stage in the example process for forming the integrated circuit configured with gate cut structures in a grating pattern, in accordance with an embodiment of the present disclosure.

FIGS. 7A-7C are plan and cross-sectional views, that illustrate another stage in the example process for forming the integrated circuit configured with gate cut structures in a grating pattern, in accordance with an embodiment of the present disclosure.

FIGS. 8A-8C are plan and cross-sectional views, that illustrate another stage in the example process for forming the integrated circuit configured with gate cut structures in a grating pattern, in accordance with an embodiment of the present disclosure.

FIGS. 9A-9C are plan and cross-sectional views, that illustrate another stage in the example process for forming the integrated circuit configured with gate cut structures in a grating pattern, in accordance with an embodiment of the present disclosure.

FIGS. 10A-10C are plan and cross-sectional views, that illustrate another stage in the example process for forming the integrated circuit configured with gate cut structures in a grating pattern, in accordance with an embodiment of the present disclosure.

FIGS. 11A-11C are plan and cross-sectional views, that illustrate another stage in the example process for forming the integrated circuit configured with gate cut structures in a grating pattern, in accordance with an embodiment of the present disclosure.

FIGS. 12A-12C are plan and cross-sectional views, that illustrate another stage in the example process for forming the integrated circuit configured with gate cut structures in a grating pattern, in accordance with an embodiment of the present disclosure.

FIGS. 13A-13C are plan and cross-sectional views, that illustrate another stage in the example process for forming the integrated circuit configured with gate cut structures in a grating pattern, in accordance with an embodiment of the present disclosure.

FIGS. 14A-14C are plan and cross-sectional views, that illustrate another stage in the example process for forming the integrated circuit configured with gate cut structures in a grating pattern, in accordance with an embodiment of the present disclosure.

FIG. 15 illustrates a cross-sectional view of a chip package containing one or more semiconductor dies, in accordance with some embodiments of the present disclosure.

FIG. 16 is a flowchart of a fabrication process for a semiconductor device having gate cut structures in a grating pattern, in accordance with an embodiment of the present disclosure.

FIG. 17 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having a grating pattern (e.g., parallel lines) of gate cut structures such that a gate cut structure extends between the gate layers of adjacent semiconductor devices and between the source or drain regions (e.g., epitaxial regions) of the adjacent semiconductor devices. The techniques can be used in any number of integrated circuit applications and are particularly useful with respect to logic and memory cells, such as those cells that use finFETs or gate-all-around transistors (e.g., ribbonFETs and nanowire FETs). In an example, neighboring semiconductor devices each include a semiconductor region extending between a source region and a drain region, and a gate structure extending over the semiconductor regions of the neighboring semiconductor devices. In some such examples, a gate cut structure is present between each pair of neighboring semiconductor devices thus interrupting the gate structure and isolating the gate electrode of one semiconductor device from the gate electrode of the other semiconductor device. According to some embodiments, the gate cut structure further extends to separate the source or drain regions of the neighboring semiconductor devices. Each of the gate cut structures may continue to extend to separate several more pairs of semiconductor devices in this way. Each of the gate cut structures may be formed, for example, at the same time in a grating pattern across the integrated circuit, or in one or more portions of the integrated circuit. According to some embodiments, a self-aligned process is performed using self-assembled polymer materials to align one or more conductive gate bridges between adjacent gate electrodes to conductively couple those gate electrodes together. Numerous variations and embodiments will be apparent in light of this disclosure.

General Overview

As previously noted above, there remain a number of non-trivial challenges with respect to integrated circuit fabrication. In more detail, gate cut structures are sometimes provided between adjacent semiconductor devices to isolate first and second portions of a gate structure that crosses over each of the adjacent semiconductor devices. Accordingly, a gate cut structure can be used to isolate the gates of two devices from one another. Forming such structures can require numerous additional masking and etching processes that can compromise the integrity of the integrated circuit. Standard gate cut structures placed at certain intervals of the integrated circuit can suffer from alignment issues such as registration variation. Furthermore, additional lithography processes to form conductive connections across any of the gate cuts introduce potential alignment errors that can cause shorting.

Thus, and in accordance with an embodiment of the present disclosure, techniques are provided herein to form a grating pattern of gate cut structures (e.g., dielectric walls) across an integrated circuit (or a portion thereof) such that the gate cut structures are all formed at the same time between adjacent pairs of semiconductor devices across the integrated circuit (or at least within the portion where the gate cut structures are formed). According to some such examples, forming gate cut structures between each device pair allows for a more streamlined masking and etching process to form the gate cut structures after most of the transistor elements have been formed (e.g., after formation of the source or drain regions and the final gate structures). According to some embodiments, the gate cut structures are formed as parallel lines extending in a first direction cutting through a series of metal gate layers extending in a second direction substantially orthogonal (e.g., within ±5 degrees of 90 degrees) to the first direction. The gate cut structures also cut between adjacent source or drain regions formed in the area between the parallel metal gate layers. The gate cut structures may be formed using a single lithographic mask (e.g., with the grating pattern) and at the same time via a single etching process and dielectric filling process. An additional benefit to using the grating pattern of gate cut structures is the removal of dead space within each of the gate structures, which lowers parasitic capacitance across the integrated circuit.

Since gate cut structures may be provided between each pair of semiconductor devices, one or more conductive gate bridges can be formed to reconnect certain gate layers together again. According to some embodiments, one or more self-assembled polymers are used to form a masking pattern over the integrated circuit to aid in the formation of the one or more conductive gate bridges. Due to the self-assembled masking process, the one or more conductive gate bridges can be self-aligned within their given gate trenches, further increasing the reliability of the integrated circuit.

According to an embodiment, an integrated circuit includes a plurality of semiconductor devices each having one or more semiconductor bodies extending in a first direction between corresponding source or drain regions, a plurality of gate layers, and a plurality of dielectric walls. Each of the plurality of gate layers extends lengthwise in a second direction different from the first direction across the one or more semiconductor bodies of a given semiconductor device of the plurality of semiconductor devices. Each of the plurality of dielectric walls extends in the first direction between multiple pairs of adjacent semiconductor devices.

According to another embodiment, an integrated circuit includes a first semiconductor device having a first semiconductor body extending lengthwise in a first direction between a first source region and a first drain region, a second semiconductor device having a second semiconductor body extending lengthwise in the first direction parallel to the first semiconductor body between a second source region and a second drain region, a gate structure extending in a second direction different from the first direction and including a first gate layer across the first semiconductor body and a second gate layer across the second semiconductor body, and a dielectric wall extending lengthwise in the first direction between the first and second source regions, the first and second drain regions, and the first and second gate layers.

According to another embodiment, an integrated circuit includes a first semiconductor body extending in a first direction from a first side of a first source or drain region, a second semiconductor body extending in the first direction from a second side of the first source or drain region, a third semiconductor body extending in the first direction from a first side of a second source or drain region, a fourth semiconductor body extending in the first direction from a second side of the second source or drain region, a first gate structure extending across the first semiconductor body in a second direction different from the first direction, a second gate structure extending across the second semiconductor body in the second direction, a third gate structure extending across the third semiconductor body in the second direction, a fourth gate structure extending across the fourth semiconductor body in the second direction, and a dielectric wall extending in the first direction between the first gate structure and the third gate structure, between the first source or drain region and the second source or drain region, and between the second gate structure and the fourth gate structure.

According to another embodiment, a method of forming an integrated circuit includes: forming a plurality of fins comprising semiconductor material extending above a top surface of a dielectric layer, the plurality of fins each extending lengthwise in a first direction; forming source or drain regions at opposite ends of the semiconductor material of each of the plurality of fins in the first direction; forming a dielectric fill between adjacent source or drain regions; forming strips of gate layers over the semiconductor material of the plurality of fins, the strips of gate layers extending lengthwise in a second direction different from the first direction; etching trenches at least through the strips of gate layers and through the dielectric fill, the trenches extending lengthwise in the second direction; and filling the trenches with a dielectric material. In some embodiments, the method further includes forming a dielectric cap layer over the strips of gate layers; forming one or more conductive contacts over corresponding one or more source or drain regions; forming one or more plugs over corresponding one or more other source or drain regions; assembling a first polymer material on the dielectric cap layer; and assembling a second polymer material on the one or more conductive contacts and the one or more plugs. In some embodiments, the method further includes replacing the first polymer material with a dielectric masking material; lithographically patterning the dielectric masking material to from openings above the dielectric cap layer; removing the exposed dielectric cap layer within the openings; and forming conductive bridges within the openings.

The techniques can be used with any type of non-planar transistors, including finFETs (sometimes called double-gate transistors, or tri-gate transistors), or nanowire and nanoribbon transistors (sometimes called gate-all-around transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of gate cut structures between every adjacent pair of semiconductor devices of a given integrated circuit, where the gate cut structures extend lengthwise between multiple pairs of semiconductor devices. In another example, such tools may be used to observe that one or more conductive gate bridges formed across corresponding gate cuts are very well aligned within their respective gate trenches (due to the self-aligned fabrication process discussed in more detail herein).

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Architecture

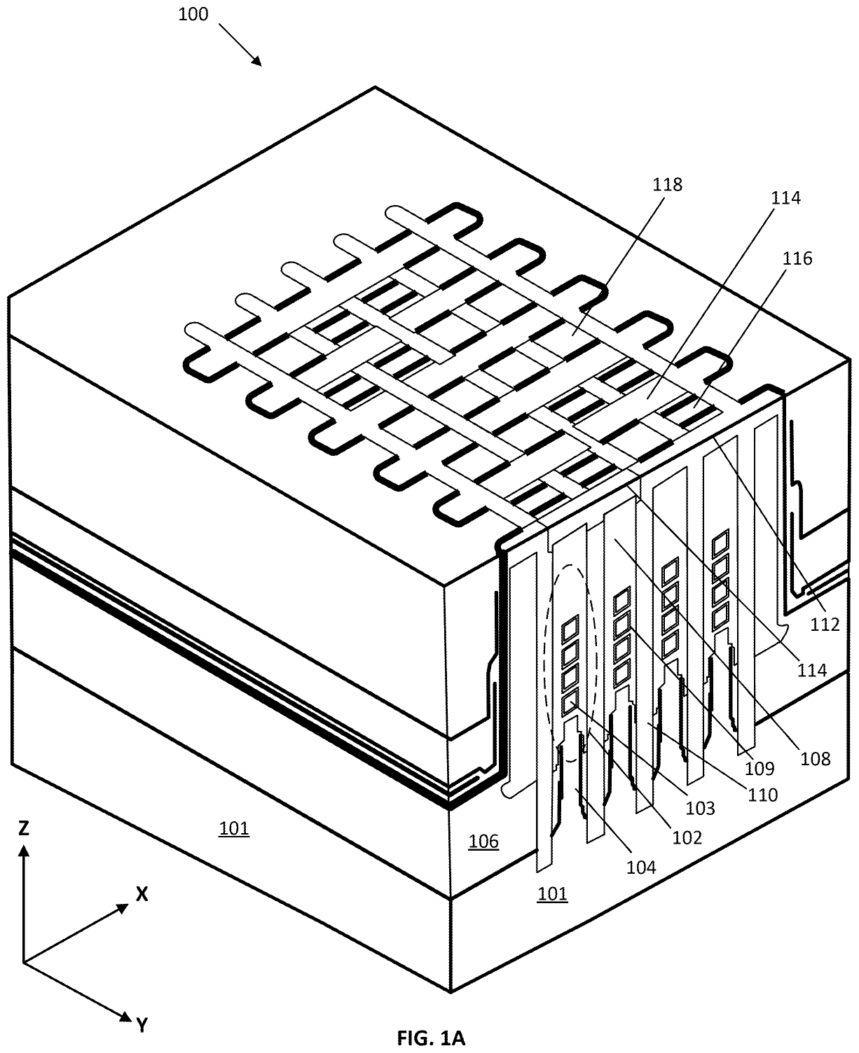

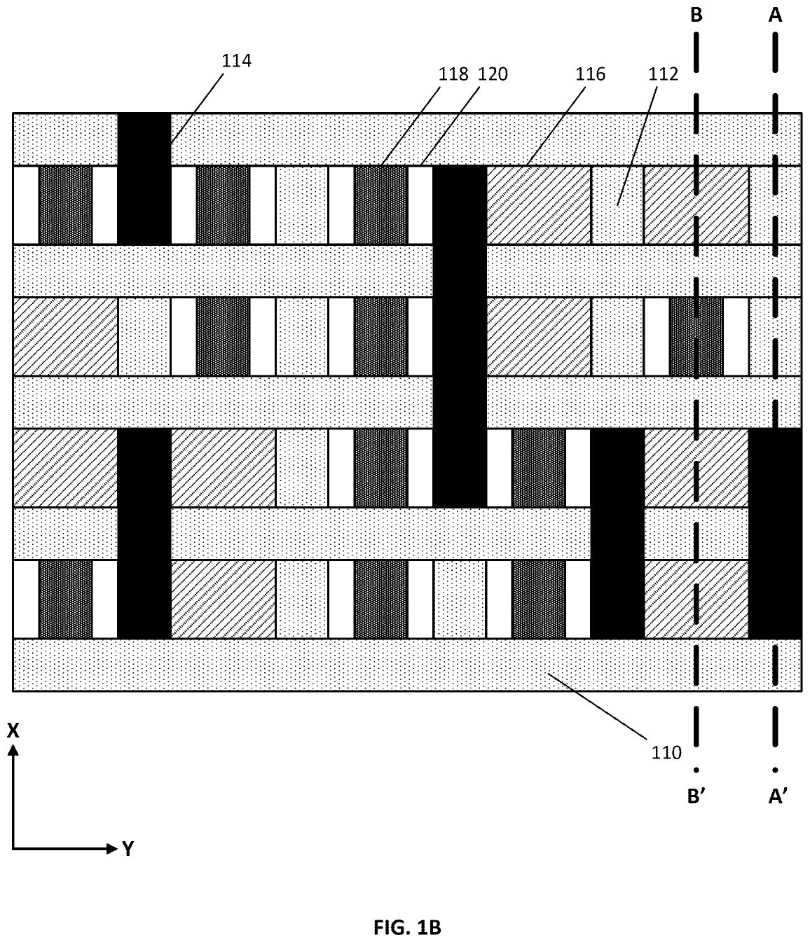

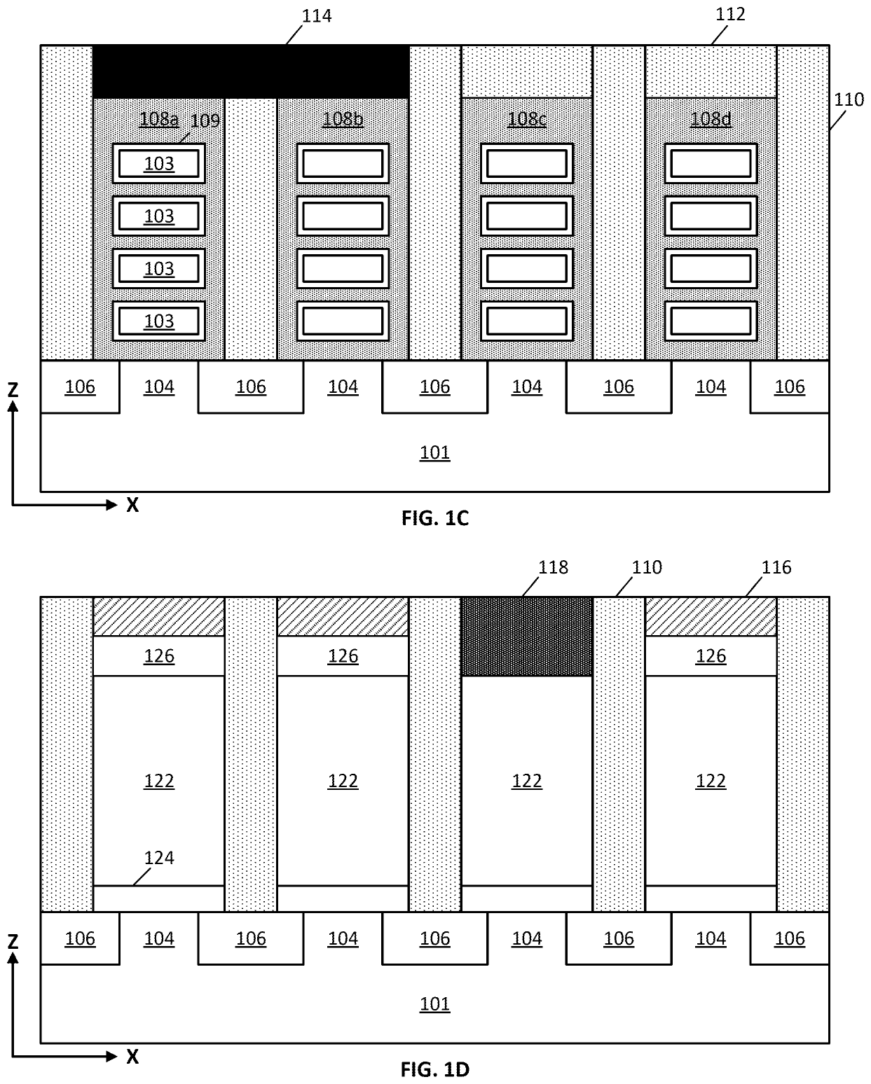

FIG. 1A is an isometric view of a portion of an integrated circuit 100 that includes various parallel semiconductor devices, in accordance with an embodiment of the present disclosure. Each of the semiconductor devices may be non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions).

The semiconductor material used in each of the semiconductor devices may be formed from a semiconductor substrate 101. Substrate 101 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of substrate 101 is removed and replaced with one or more backside interconnect layers to form backside signal and power routing.

The one or more semiconductor regions of the devices may include fins that can be, for example, native to substrate 101 (formed from the substrate itself), such as silicon fins etched from a bulk silicon substrate. Alternatively, the fins can be formed of material deposited onto substrate 101. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons during a gate forming process where one type of the alternating layers is selectively etched away so as to liberate the other type of alternating layers within the channel region, so that a gate-all-around process can then be carried out. Again, the alternating layers can be blanket deposited and then etched into fins or deposited into fin-shaped trenches.

Each semiconductor device 102 includes one or more semiconductor regions, such as one or more nanoribbons 103 extending between epitaxial source or drain regions (not shown in this view) in a first direction along the Y-axis. According to some embodiments, semiconductor devices 102 further include a subfin region 104 that extends vertically (e.g., along the Z-axis) between a top surface of substrate 101 and one or more nanoribbons 103. According to some embodiments, subfin region 104 is a portion of the corresponding semiconductor fin that remains after formation of the various transistors and may be formed from substrate 101. Accordingly, subfin region 104 may include the same semiconductor material as substrate 101 (or any semiconductor material in situations where substrate 101 is removed). Subfin region 104 may also be an insulator (for example oxide or nitride) separating gate layer 108 from substrate 101. In some embodiments, subfin region 104 extends through a dielectric fill 106 that acts as shallow trench isolation (STI) between devices. Dielectric fill 106 can be any suitable dielectric material, such as silicon oxide.

A gate structure that includes gate layer (or electrode) 108 and a gate dielectric 109 extends over the one or more semiconductor regions of a given semiconductor device 102 in a second direction along the X-axis to form the transistor gate. Gate layer 108 may represent any number of conductive layers and gate dielectric 109 may represent any number of dielectric layers. Gate layer 108 may include any sufficiently conductive material such as a metal, metal alloy, or doped polysilicon. In some embodiments, gate layer 108 includes one or more workfunction metals around the one or more semiconductor regions. In some embodiments, p-channel devices include a workfunction metal having titanium around its one or more semiconductor regions and n-channel devices include a workfunction metal having tungsten around its one or more semiconductor regions. Gate layer 108 may also include a fill metal or other conductive material around the workfunction metals to provide the whole gate electrode structure. Gate dielectric 109 may include any suitable gate dielectric material(s). In some embodiments, gate dielectric 109 includes a layer of native oxide material (e.g., silicon oxide) on the nanoribbons or other semiconductor regions making of the channel region of devices 102, and a layer of high-k dielectric material (e.g., hafnium oxide) on the native oxide.

According to some embodiments, adjacent gate layers 108 around adjacent semiconductor devices 102 are separated from one another along the X-axis by dielectric walls 110. Any number of suitable dielectric materials can be used for dielectric walls 110, such as silicon nitride or silicon oxynitride or low-K versions of these (e.g., porous silicon oxynitride). In some examples, the dielectric material of dielectric walls 110 is etch selective with respect to dielectric fill 106. Dielectric walls 110 may run lengthwise parallel to one another along the Y-axis and extend along the Z-axis at least into dielectric fill 106 and up to either a cap layer 112 or a conductive bridge 114. According to some embodiments, dielectric walls 110 continue to extend along the Y-axis between multiple pairs of semiconductor devices and between the source or drain regions of the devices as described in more detail below.

The dielectric cap layer 112 may be provided across a top surface of a plurality of adjacent gate layers 108 and may run lengthwise along the X-axis. Cap layer 112 may include the same dielectric material as dielectric walls 110, in some examples. According to some embodiments, portions of cap layer 112 are interrupted by any number of conductive bridges 114. Conductive bridges 114 can include any suitable conductive material, such as tungsten or other metals. Conductive bridge 114 may be present to conductively couple any number of adjacent gate layers 108 together to provide local interconnects between devices.

According to some embodiments, any number of dummy contacts 116 and contacts 118 may be formed between semiconductor devices along the Y-axis. Contacts 118 may include any suitable conductive material, such as tungsten, to make electrical contact with an underlying source or drain region. Dummy contacts 116 may include a material that includes a metal element, but has a relatively low conductivity, such as a metal oxide. In some embodiments, dummy contacts 116 include aluminum oxide, and do not make electrical contact with an underlying source or drain region. The distinction between the two types of contacts is described in more detail below. Dummy contacts 116 and contacts 118 may be formed in any pattern across integrated circuit 100.

FIG. 1B illustrates a plan view of integrated circuit 100, and FIGS. 1C and 1D each illustrate cross-section views of integrated circuit 100 taken across plane A-A′ and plane B-B′, respectively. As seen in FIG. 1B, spacer structures 120 may be present along sidewall portions of the gate structures and corresponding cap layers 112. Spacer structures 120 may be formed from any suitable dielectric material, and may be the same dielectric material as cap layers 112 and/or dielectric walls 110. Accordingly, there may not be any noticeable seams or boundaries between any of dielectric walls 110, cap layers 112, or spacer structures 120 depending on the materials used. Various conductive bridges 114 are shown with some extending across more than two semiconductor devices.

It should be noted that the dimensions of various elements are not intended to be drawn to scale. For example, the width of cap layers 112 (e.g., along the Y-axis) may be greater than the width of dielectric walls 110 (e.g., along the X-axis). For instance, in some examples, the width of cap layers 112 may be at least 1.5×, at least 2×, at least 2.5×, at least 3×, or at least 4× wider than the width of dielectric walls 110.

FIG. 1C illustrates a cross-section across the nanoribbons 103 of multiple adjacent semiconductor devices. Dielectric walls 110 pass between each adjacent pair of semiconductor devices to split (“cut”) gate layer 108 into separate distinct gate layers 108a-108d. Conductive bridge 114 is shown conductively connecting gate layers 108a with 108b, while gate layers 108c and 108d remain separated.

FIG. 1D illustrates another cross-section across the source or drain regions 122 formed between the ends of the semiconductor bodies (e.g., nanoribbons 105). Any of source or drain regions 122 may act as either a source region or a drain region, depending on the application and dopant profile. Any semiconductor materials suitable for source and drain regions can be used (e.g., group IV and group III-V semiconductor materials) for any of the illustrated source or drains regions 122. In any such cases, the composition and doping of source or drain regions 122 may be the same or different, depending on the polarity of the transistors. For example, any semiconductor devices that are p-type MOS (PMOS) transistors have a high concentration of p-type dopants in the associated source or drain regions 122, and any semiconductor devices that are n-type MOS (NMOS) transistors have a high concentration of n-type dopants in the associated source or drain regions 122. Any number of source and drain configurations and materials can be used. In some embodiments, source or drain regions 122 are separated from the underlying subfin regions 104 by a lower dielectric layer 124 that can be any suitable dielectric material. Furthermore, a top dielectric layer 126 may be present between source or drain regions 122 that have dummy contacts 116. Top dielectric layer 126 may be provided to prevent dummy contacts 116 from directly contacting source or drain regions 122. In some other embodiments, top dielectric layer 126 is not present such that dummy contacts 116 contact a top portion of source or drain regions 122.

As noted above, dielectric walls 110 extend between adjacent ones of source or drain regions 122. In some examples, dielectric walls 110 extend down into at least a portion of dielectric fill 106 or extend down into a portion of substrate 101 (e.g., through an entire thickness of dielectric fill 106).

Fabrication Methodology

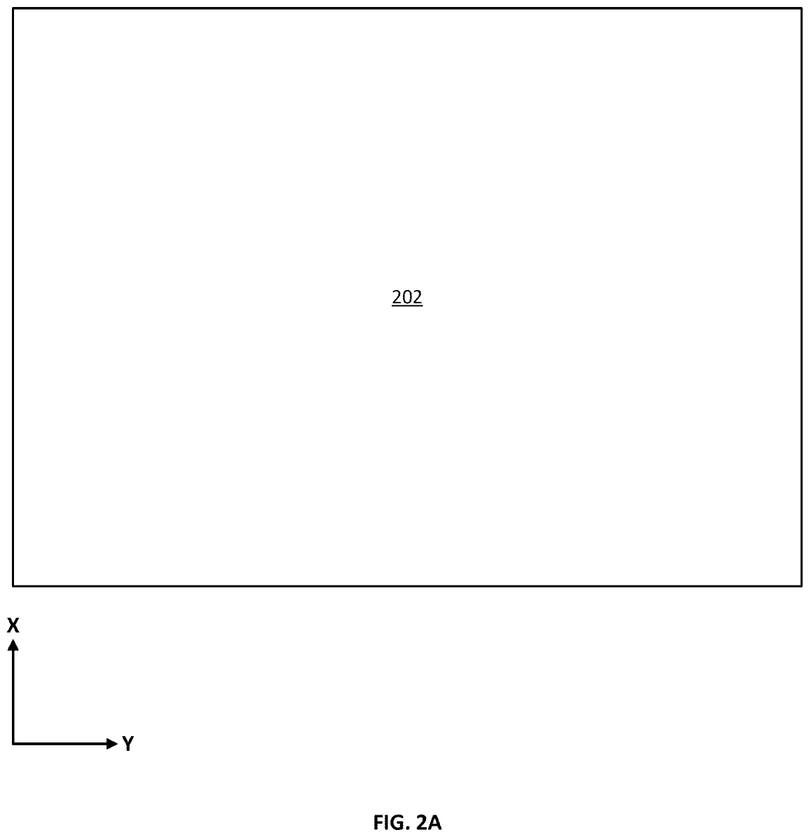

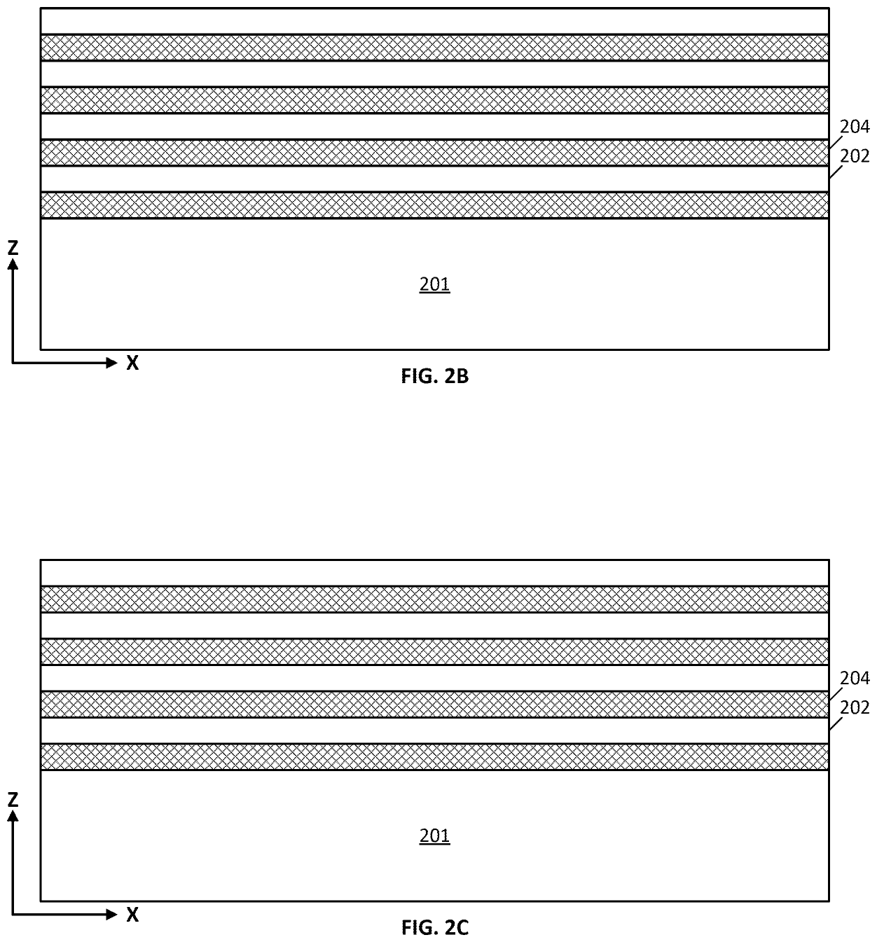

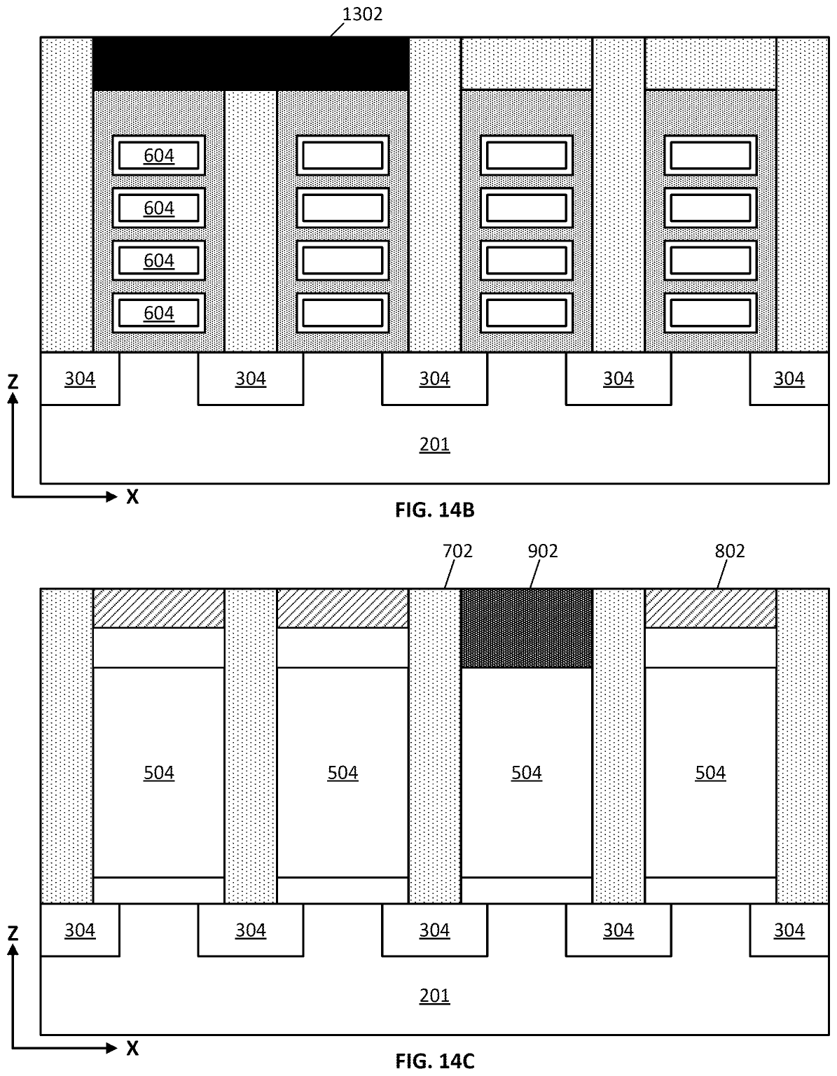

FIGS. 2A-14A, 2B-14B, and 2C-14C include cross-sectional and plan views that collectively illustrate an example process for forming an integrated circuit configured with gate cut structures in a grating pattern, in accordance with an embodiment of the present disclosure. FIGS. 2A-14A represent a similar plan view to that shown in FIG. 1B, while FIGS. 2B-14B represent a cross-sectional view taken across plane A-A′ in FIG. 1B, while FIGS. 2C-14C represent a cross-sectional view taken across plane B-B′ in FIG. 1B. Each set of figures sharing the same letter shows an example structure that results from the process flow up to that point in time, so the depicted structure evolves as the process flow continues, culminating in the structure shown in FIGS. 14A-14C, which is similar to the structure shown in FIGS. 1B-1D. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 2A illustrates a plan view showing only a top-most deposited semiconductor layer 202, according to an embodiment. FIGS. 2B and 2C each illustrates a cross-sectional view taken through a substrate 201 having a series of material layers formed over the substrate, according to an embodiment of the present disclosure. Alternating material layers may be deposited over substrate 201 including semiconductor layers 202 alternating with sacrificial layers 204. The alternating layers are used to form GAA transistor structures. Any number of alternating semiconductor layers 202 and sacrificial layers 204 may be deposited over substrate 201. The description above for substrate 101 applies equally to substrate 201.

According to some embodiments, sacrificial layers 204 have a different material composition than semiconductor layers 202. In some embodiments, sacrificial layers 204 are silicon germanium (SiGe) while semiconductor layers 202 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 204 and in semiconductor layers 202, the germanium concentration is different between sacrificial layers 204 and semiconductor layers 202. For example, sacrificial layers 204 may include a higher germanium content compared to semiconductor layers 202. In some examples, semiconductor layers 202 may be doped with either n-type dopants (to produce a p-channel transistor) or p-type dopants (to produce an n-channel transistor).

While dimensions can vary from one example embodiment to the next, the thickness of each sacrificial layer 204 may be between about 5 nm and about 20 nm. In some embodiments, the thickness of each sacrificial layer 204 is substantially the same (e.g., within 1-2 nm). The thickness of each of semiconductor layers 202 may be about the same as the thickness of each sacrificial layer 204 (e.g., about 5-20 nm). Each of sacrificial layers 204 and semiconductor layers 202 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

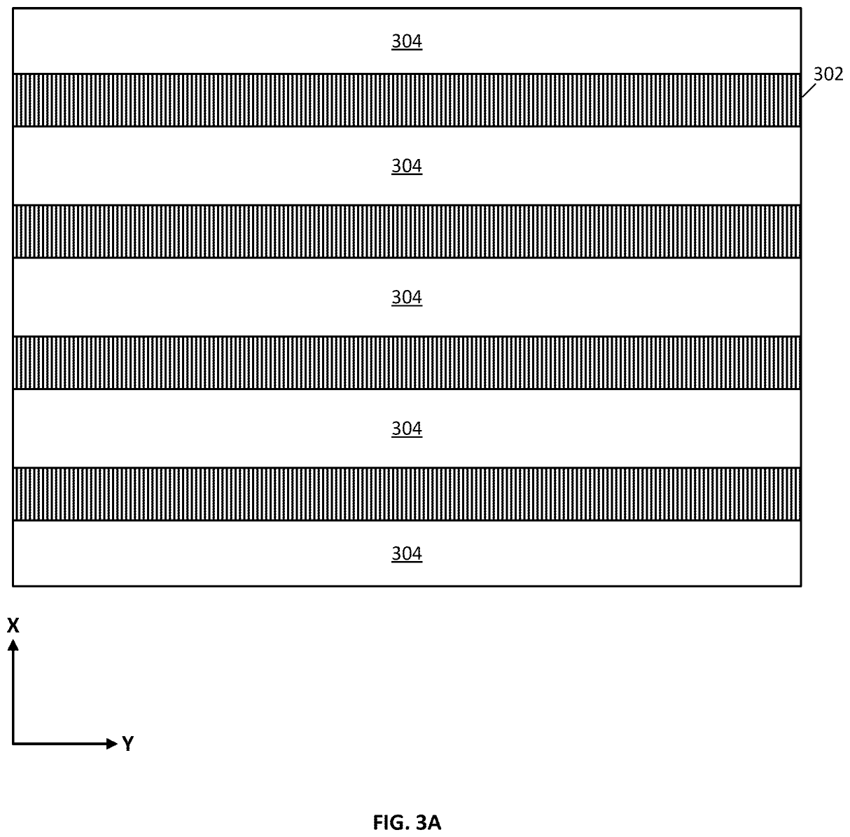

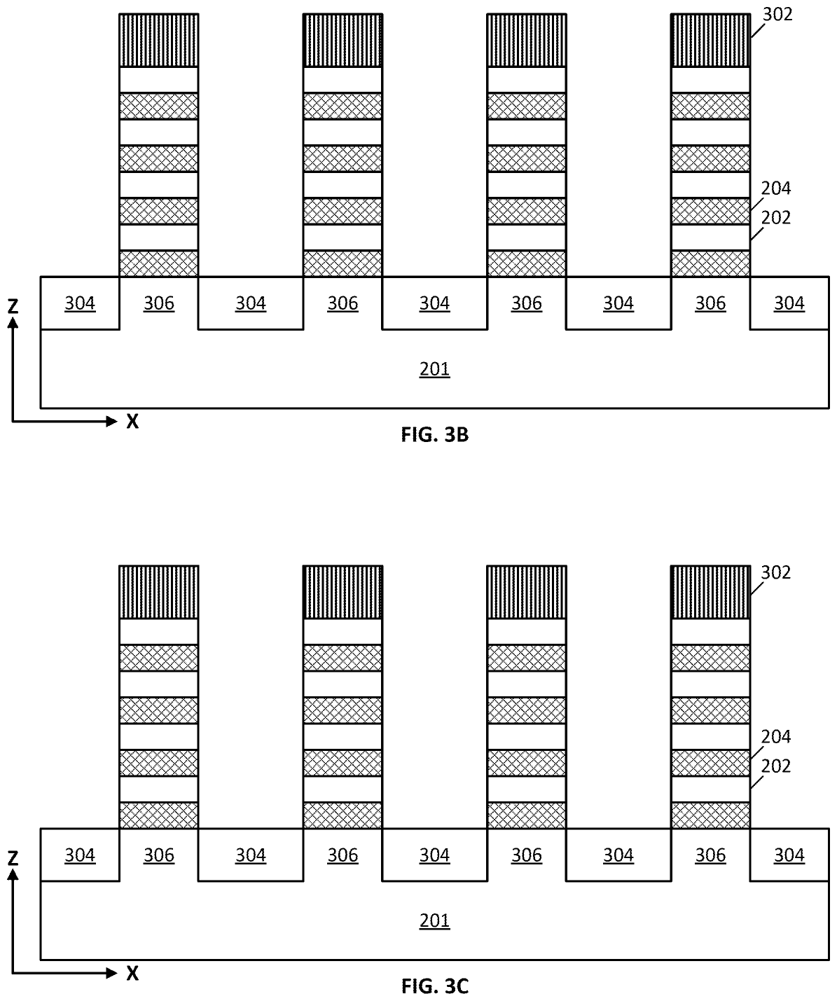

FIGS. 3A-3C depict plan and cross-section views of the structures shown in FIGS. 2A-2C following the formation of a cap layer 302 and the subsequent formation of fins beneath cap layer 302, according to an embodiment. Cap layer 302 may be any suitable hard mask material such as a carbon hard mask (CHM), silicon oxide, or silicon nitride. Cap layer 302 is patterned into rows to form corresponding rows of fins from the alternating layer stack of sacrificial layers 204 and semiconductor layers 202.

According to some embodiments, an anisotropic etching process through the layer stack continues into at least a portion of substrate 201. The etched portion of substrate 201 may be filled with a dielectric fill 304 that acts as shallow trench isolation (STI) between adjacent fins. Dielectric fill 304 may be any suitable dielectric material such as silicon oxide. Subfin regions 306 represent remaining portions of substrate 201 between dielectric layer 304, according to some embodiments. Subfin regions 306 may also be replaced with a dielectric such as silicon oxide or silicon nitride. FIG. 3A illustrates how dielectric layer 304 extends along the entire length of each of the fins, according to some embodiments.

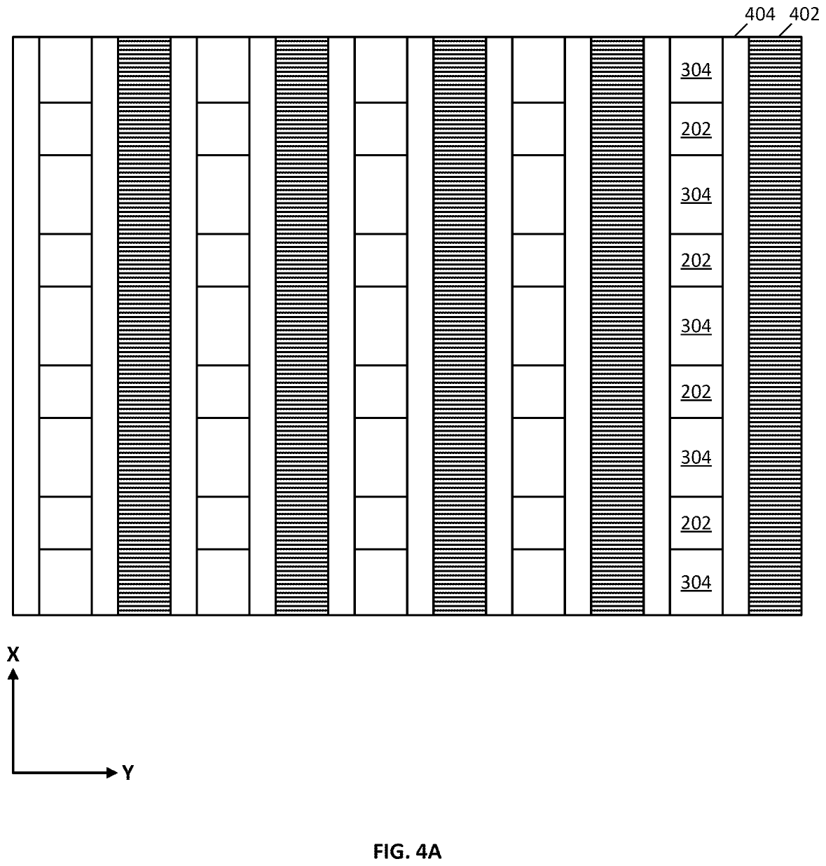

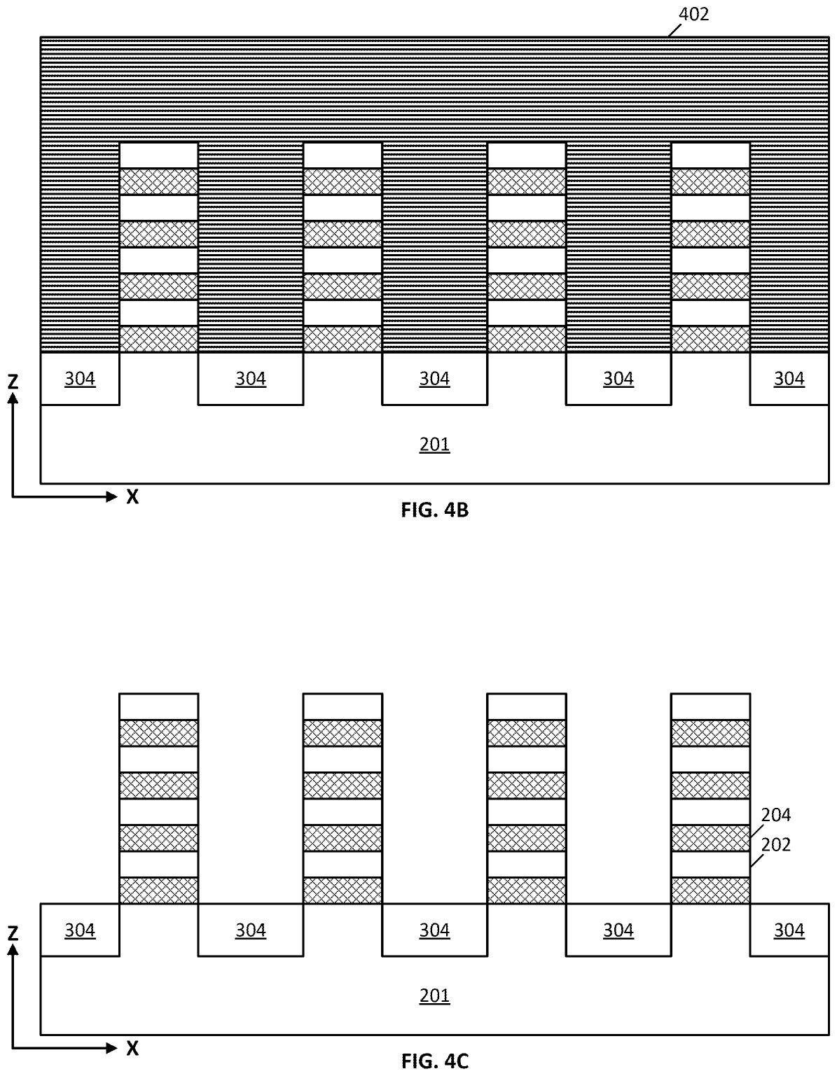

FIGS. 4A-4C depict plan and cross-section views of the structures shown in FIGS. 3A-3C following the formation of a sacrificial gate 402, according to some embodiments. A gate masking layer may first be patterned in strips that extend orthogonally across each of the fins in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any suitable material that can be selectively removed without damaging the semiconductor material of the fins. In some examples, sacrificial gate 402 includes polysilicon. FIG. 4B illustrates sacrificial gate 402 extending lengthwise across multiple fins along the X-axis while FIG. 4C shows the absence of the sacrificial gate across portions of the fins between the rows of sacrificial gates 402.

According to some embodiments, sidewall structures 404 are formed along the sidewalls of sacrificial gates 402. Spacer structures 404 may be deposited and then etched back such that spacer structures 404 remain mostly only on sidewalls of any exposed structures. In the plan view of FIG. 4A, spacer structures 404 may also be formed along sidewalls of the exposed fins (having a top semiconductor layer 202) over dielectric fill 304. Such sidewall spacers on the fins can be removed during later processing when forming the source or drain regions. According to some embodiments, spacer structures 404 may be any suitable dielectric material, such as silicon nitride, silicon carbon nitride, or silicon oxycarbonitride. In one such embodiment, spacer structures 404 comprise a nitride and dielectric fill 304 comprises an oxide, so as to provide a degree of etch selectivity during final gate processing. Other etch selective dielectric schemes (e.g., oxide/carbide, carbide/nitride) can be used as well for spacer structures 404 and dielectric fill 304. In other embodiments, spacer structures 404 and dielectric fill 304 are compositionally the same or otherwise similar, where etch selectivity is not employed.

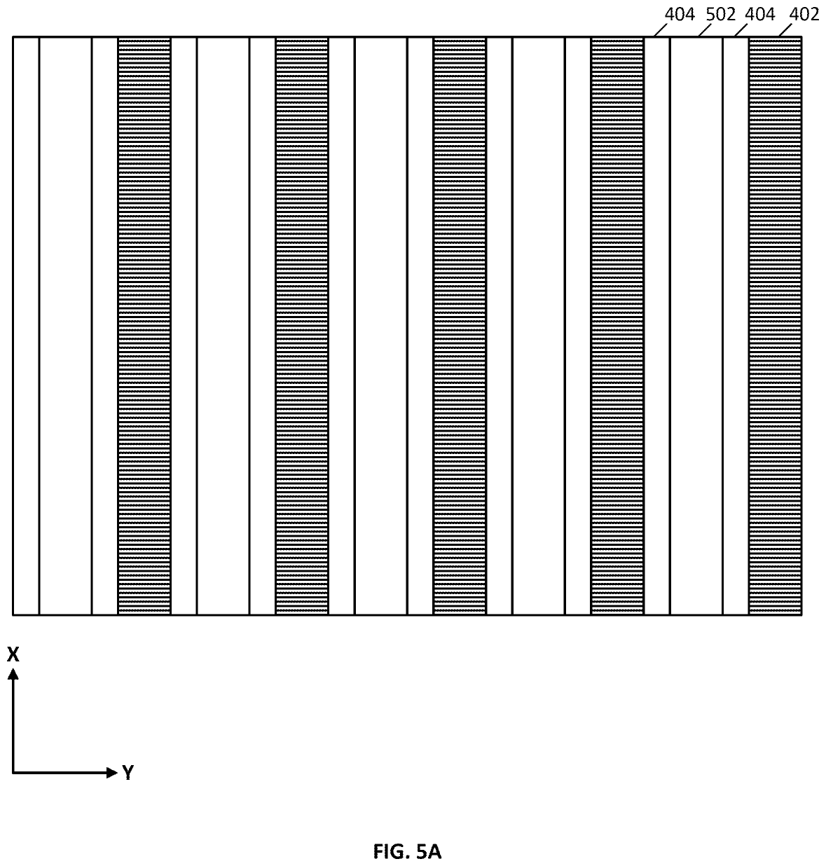

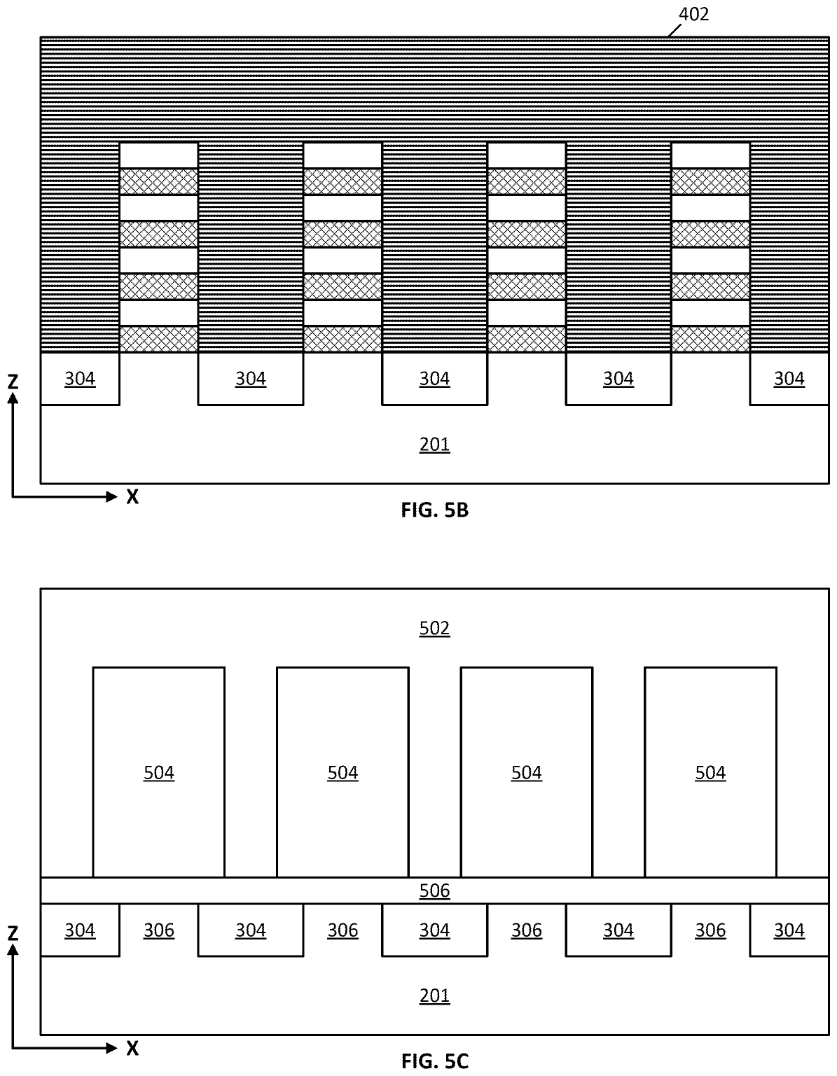

FIGS. 5A-5C depict plan and cross-section views of the structures shown in FIGS. 4A-4C following the formation of source or drain regions at the ends of the fins outside of the regions covered by sacrificial gate 402 and spacer structures 404, according to some embodiments. The plan view in FIG. 5A shows another dielectric fill 502 between adjacent spacer structures 404, which protects the source or drain regions formed beneath it. In more detail, and according to an example, exposed portions of the fins between spacer structures 404 are removed. The exposed fin portions may be removed using any anisotropic etching process, such as reactive ion etching (RIE). Once the exposed fins have been removed, source or drain regions 504 may be formed in the areas that had been previously occupied by the exposed fins between spacer structures 404. According to some embodiments, source or drain regions 504 are epitaxially grown from the exposed semiconductor material of the fins (or nanoribbons, nanowires or nanosheets, as the case may be) along the exterior walls of spacer structures 404. In some example embodiments, source or drain regions 504 are NMOS source or drain regions (e.g., epitaxial silicon) or PMOS source or drain regions (e.g., epitaxial SiGe).

According to some embodiments, a lower dielectric layer 506 may first be deposited before forming source or drain regions 504 to isolate source or drain regions 504 from the underlying subfin regions 306. Lower dielectric layer 506 may be any suitable dielectric material, such as silicon oxide, silicon nitride, or silicon oxynitride. According to some embodiments, dielectric fill 502 is provided in any areas between adjacent source or drain regions 504. Dielectric fill 502 may be any suitable dielectric material, such as silicon oxide. In some examples, dielectric fill 502 also extends over a top surface of source or drain regions 504 (e.g., up to and planar with a top surface of spacer structures 404). One or more conductive contacts may be formed at a later time through dielectric fill 502 to provide electrical contact to source or drain regions 504.

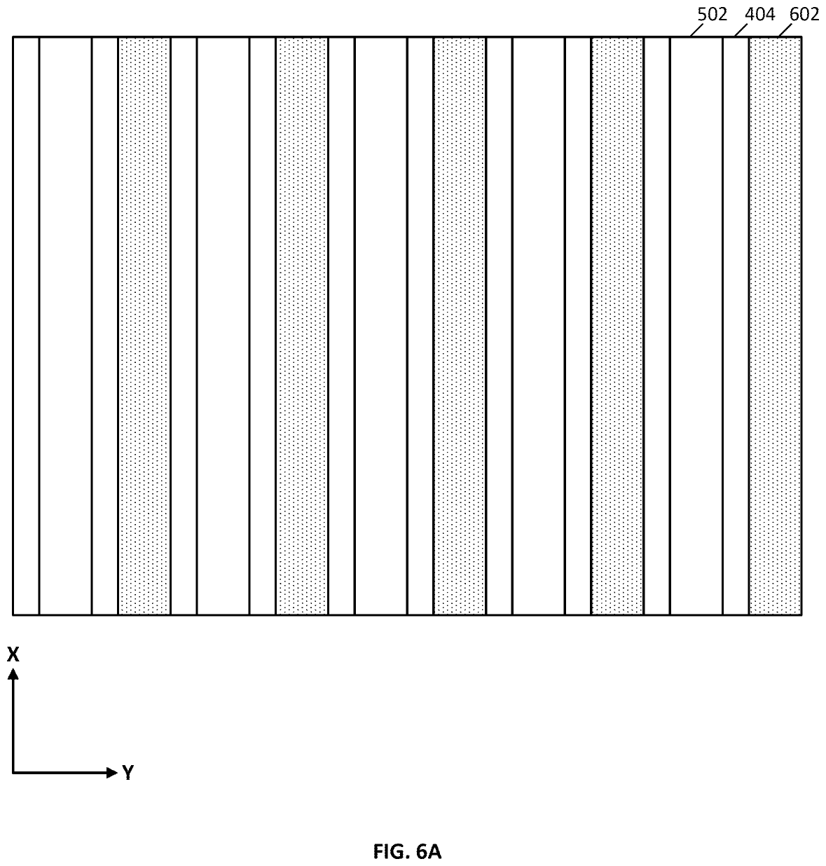

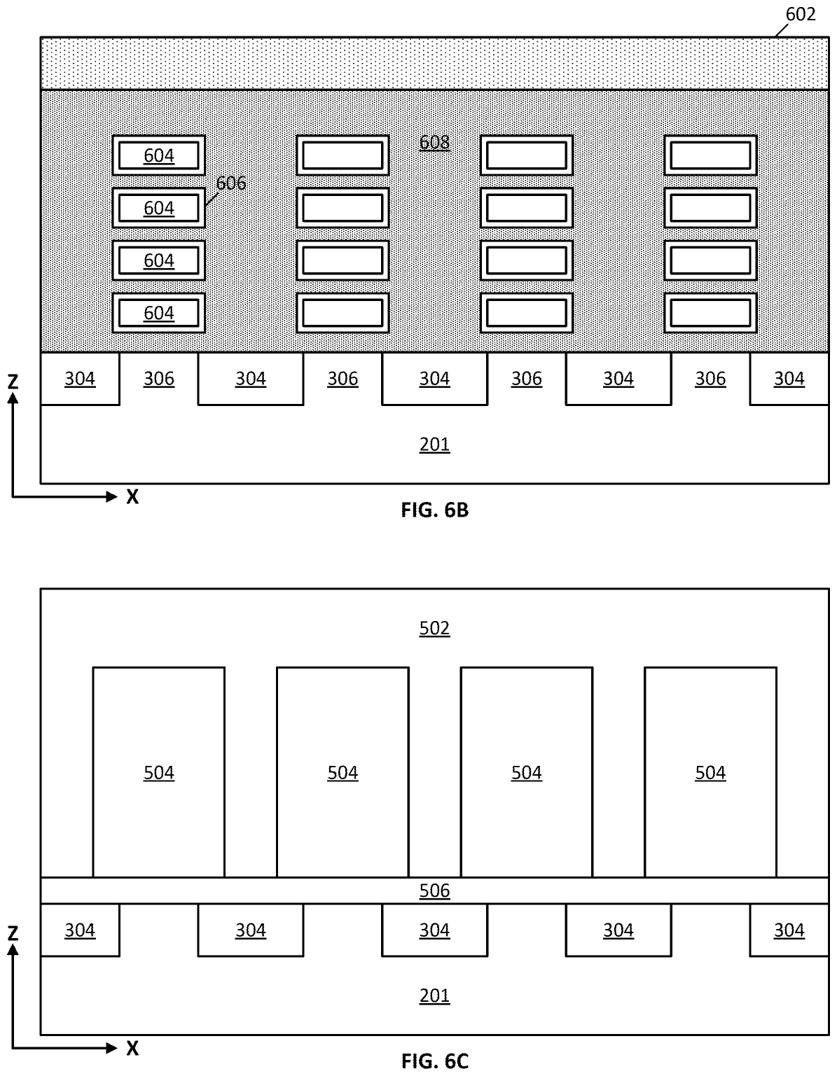

FIGS. 6A-6C depict plan and cross-section views of the structures shown in FIGS. 5A-5C following the removal of sacrificial gates 402 and sacrificial layers 204 and replacement of sacrificial gates 402 with gate structures, according to some embodiments. In examples where gate masking layers are still present over sacrificial gates 402, they would be removed at this time. The plan view of FIG. 6A illustrates dielectric cap layers 602 running lengthwise along the X-axis over underlying gate structures. In the example where the fins include alternating semiconductor layers, the exposed sacrificial layers 204 between spacer structures 404 are selectively removed to leave behind nanoribbons 604 that extend between corresponding source or drain regions 504. Each vertical set of nanoribbons 604 represents the semiconductor region of a different semiconductor device. It should be understood that nanoribbons 604 may also be nanowires or nanosheets. Sacrificial gates 402 and sacrificial layers 204 may be removed using the same isotropic etching process or different isotropic etching processes.

After the removal of sacrificial gates 402 and sacrificial layers 204, gate structures can be formed in the trenches left behind by the removal of sacrificial gates 402. Each gate structure includes a gate dielectric 606 and a gate electrode 608. Gate dielectric 606 may be first formed around nanoribbons 604 prior to the formation of the conductive gate electrode 608. The gate dielectric 606 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 606 includes a layer of hafnium oxide with a thickness between about 1 nm and about 5 nm. In some embodiments, gate dielectric 606 may include one or more silicates (e.g., titanium silicate, tungsten silicate, niobium silicate, and silicates of other transition metals). In some cases, gate dielectric 606 may include a first layer on nanoribbons 604, and a second layer on the first layer. The first layer can be, for instance, an oxide of the semiconductor material of nanoribbons 604 (e.g., silicon dioxide) and the second layer can be a high-k dielectric material (e.g., hafnium oxide). In some embodiments, gate dielectric 606 also forms along all surfaces exposed within the gate trench between spacer structures 404, such as on the top surfaces of dielectric fill 304 and subfin regions 306, and along inner sidewalls of spacer structures 404.

The gate electrode 608 may be deposited using electroplating, electroless plating, CVD, PECVD, ALD, or PVD, to name a few examples. In some embodiments, gate electrode 608 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 608 may include, for instance, a metal fill material along with one or more workfunction layers, resistance-reducing layers, and/or barrier layers. The workfunction layers can include, for example, p-type workfunction materials (e.g., titanium nitride) for PMO S gates, or n-type workfunction materials (e.g., titanium aluminum carbide) for NMOS gates. As noted above, a dielectric cap layer 602 may be formed over a top surface of the gate structure, such that cap layers 602 run parallel to one another and lengthwise along the X-axis, according to some embodiments.

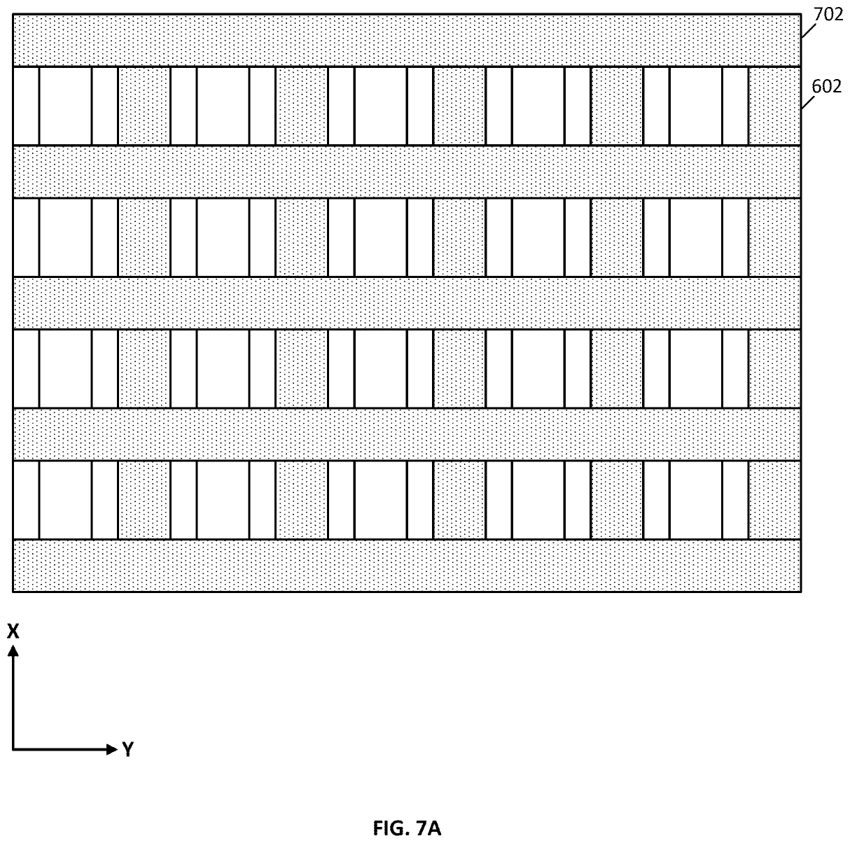

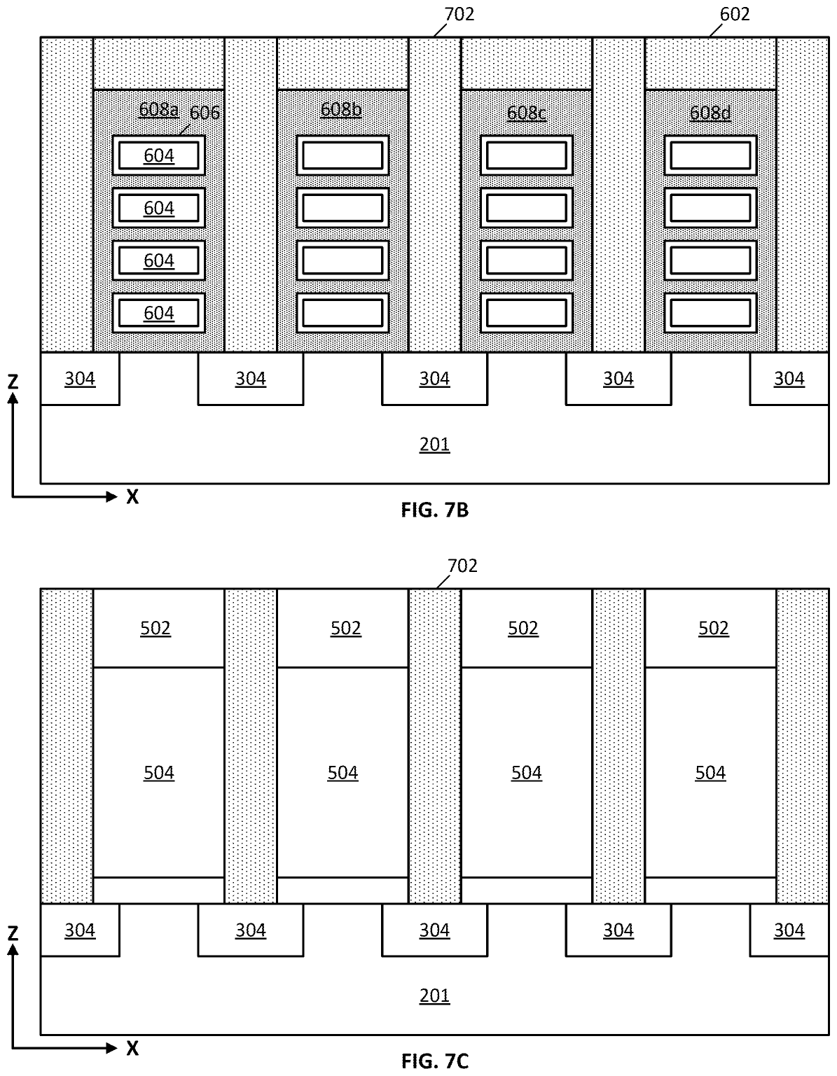

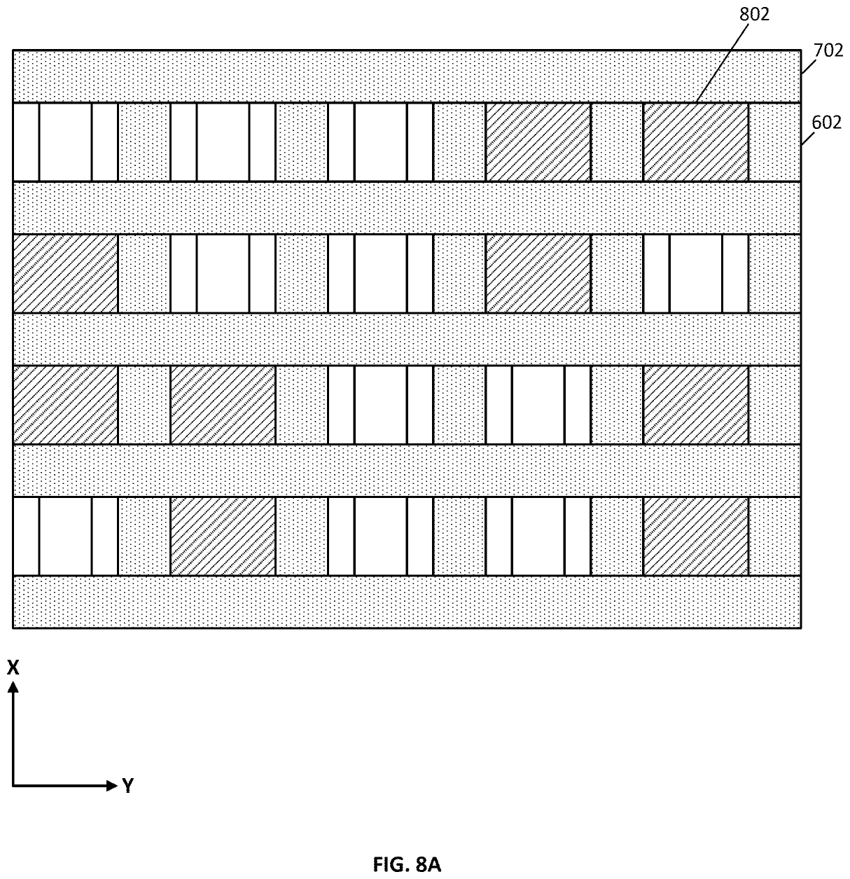

FIGS. 7A-7C depict plan and cross-section views of the structures shown in FIGS. 6A-6C following the formation of dielectric walls 702, according to some embodiments. Dielectric walls 702 may be substantially parallel to one another and run lengthwise along the Y-axis to cut between adjacent pairs of semiconductor devices. Dielectric walls 702 may be any suitable dielectric material. In one example, dielectric walls 702 have the same dielectric material as cap layers 602. As noted above, the width of dielectric walls 702 along the X-axis is lower that the width of cap layers 602 along the Y-axis, such as at least 1.5×, at least 2×, at least 2.5×, at least 3×, or at least 4× lower in width.

As seen in the cross-section views of both FIGS. 7B and 7C, dielectric walls 702 cut through the gate structures and between source or drain regions 504. A given gate structure is separated into smaller gate structures, such as those that include gate electrodes 608a-608d with each gate electrode electrically isolated from one another via dielectric walls 702. Dielectric walls 702 may cut through portions of dielectric fill 502 that were between source or drain regions 504 or dielectric walls 702 can cut through merged portions of source or drain regions 504, thus separating the source or drain regions from one another. As noted above, dielectric walls 702 may extend into a portion of dielectric fill 304 or into a portion of substrate 201. In some embodiments, dielectric walls 702 extend at least down to the top surface of dielectric fill 304.

According to some embodiments, dielectric walls 702 may be formed by etching parallel trenches extending lengthwise along the Y-axis through the various material layers. A single etching process may be used to form all of the trenches through a single mask having a grating pattern. A reactive ion etching (RIE) process may be used to cut through the various material layers and form the trenches. Afterwards, any mask layers are removed, and the trenches can be filled with a dielectric material and polished to form dielectric walls 702.

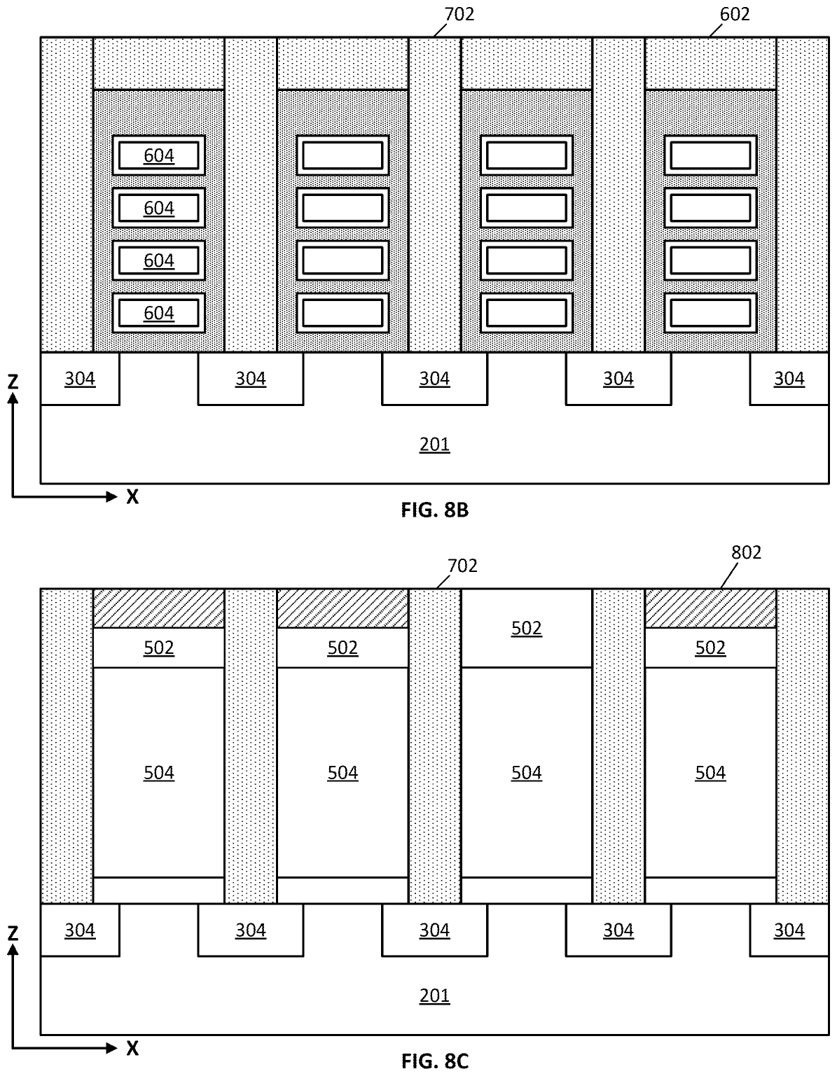

FIGS. 8A-8C depict plan and cross-section views of the structures shown in FIGS. 7A-7C following the formation of any number of dummy contacts 802, according to some embodiments. A mask may be used to protect certain windows above certain source or drain regions while an etching process is performed to recess or remove dielectric fill 502 in the unprotected windows. FIG. 8C illustrates how dielectric fill 502 may be recessed over certain source or drain regions 504. In some other embodiments, dielectric fill 502 is completely removed. In some embodiments, portions of spacer structures 404 may remain between dummy contacts 802 and cap layers 602.

Dummy contacts 802 may be formed by depositing a material containing a metal within the openings such that dummy contacts 802 form on dielectric fill 502 or over the exposed source or drain regions 504. In some embodiments, dummy contacts 802 are formed from a metal oxide, such as aluminum oxide or titanium oxide, to name a few examples. According to some embodiments, dummy contacts 802 may be any metal-containing compound that is electrically insulating.

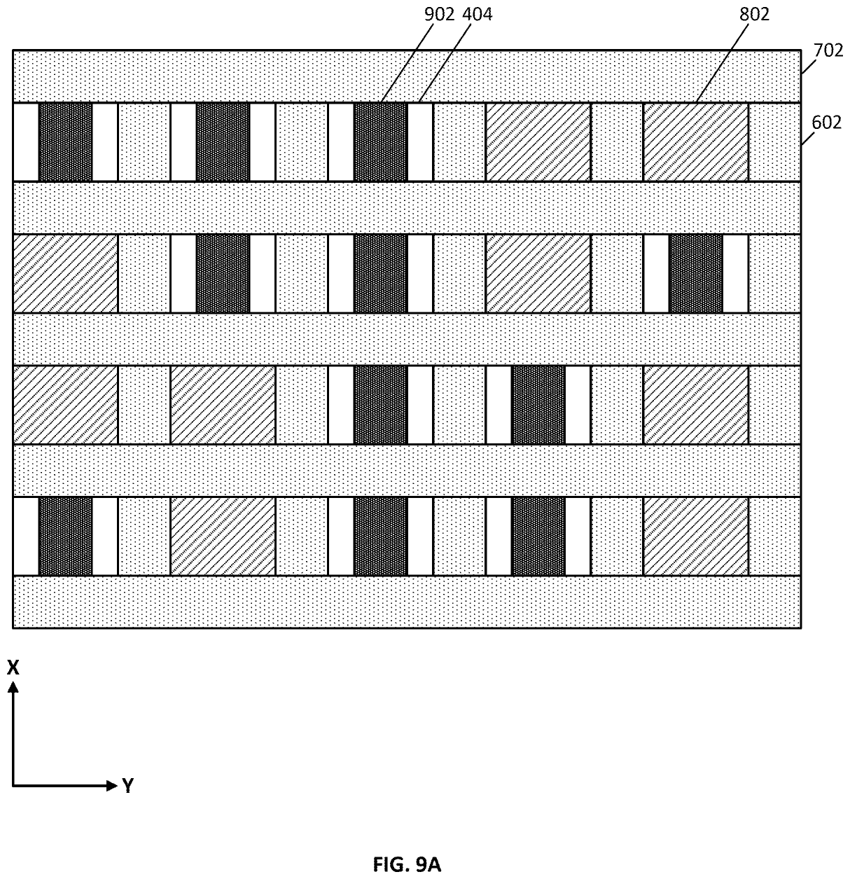

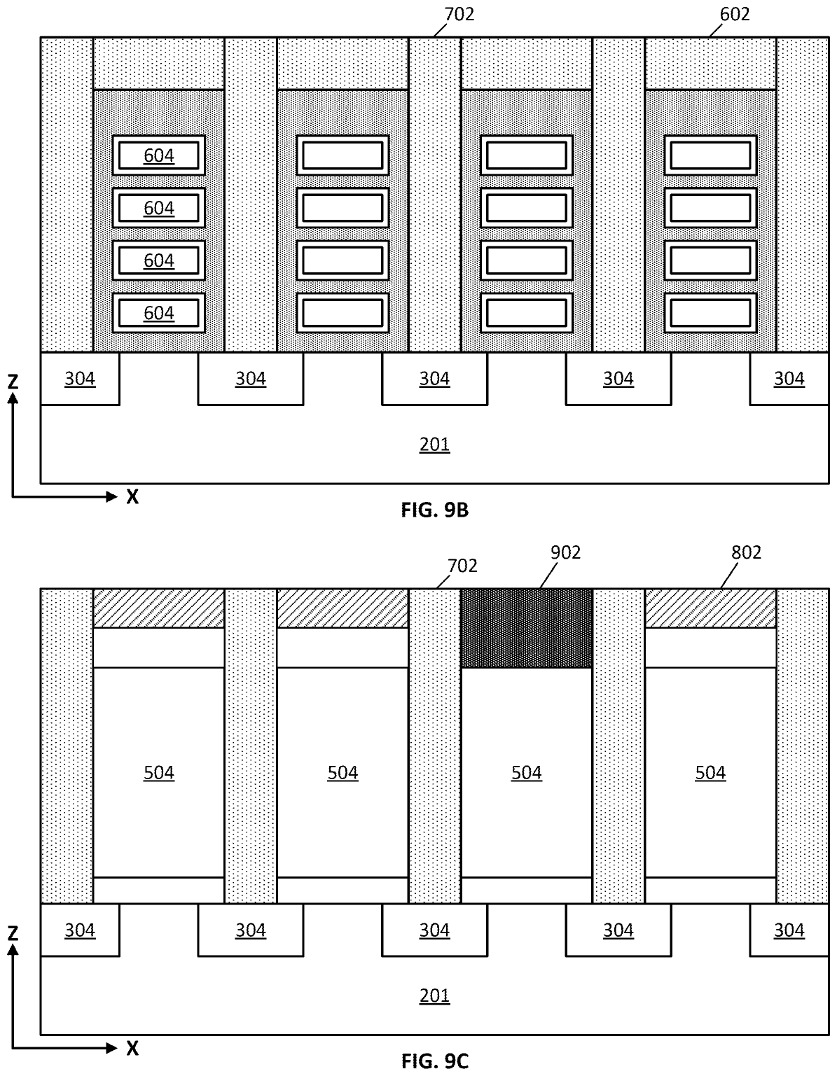

FIGS. 9A-9C depict plan and cross-section views of the structures shown in FIGS. 8A-8C following the formation of any number of contacts 902, according to some embodiments. In some examples, contacts 902 are formed over each source or drain region 504 that does not have a dummy contact 802, such that every source or drain region 504 will have either dummy contact 802 or contact 902 formed over it. Contacts 902 may include any suitable conductive material, such as tungsten, molybdenum, or ruthenium, for making electrical contact with the underlying source or drain regions 504. As seen in the cross section of FIG. 9C, dielectric fill 502 is removed from above any number of source or drain regions 504 and contact 902 is formed within the opening using any suitable metal deposition process to make conductive contact with the underlying source or drain region 504. The final structure is then polished to planarize the top surfaces of both contacts 902 and dummy contacts 802.

In some embodiments, spacer structures 404 (or at least portions of spacer structures 404) remain on opposite ends of contacts 902 as seen in FIG. 9A. In other examples, these spacer structures are removed during or in addition to the removal of dielectric fill 502. At this point in the fabrication process, the plan view of the integrated circuit will show a crisscross pattern of cap layers 602 and dielectric walls 702 with rows and columns of either dummy contacts 802 or contacts 902 in any arrangement, according to some embodiments.

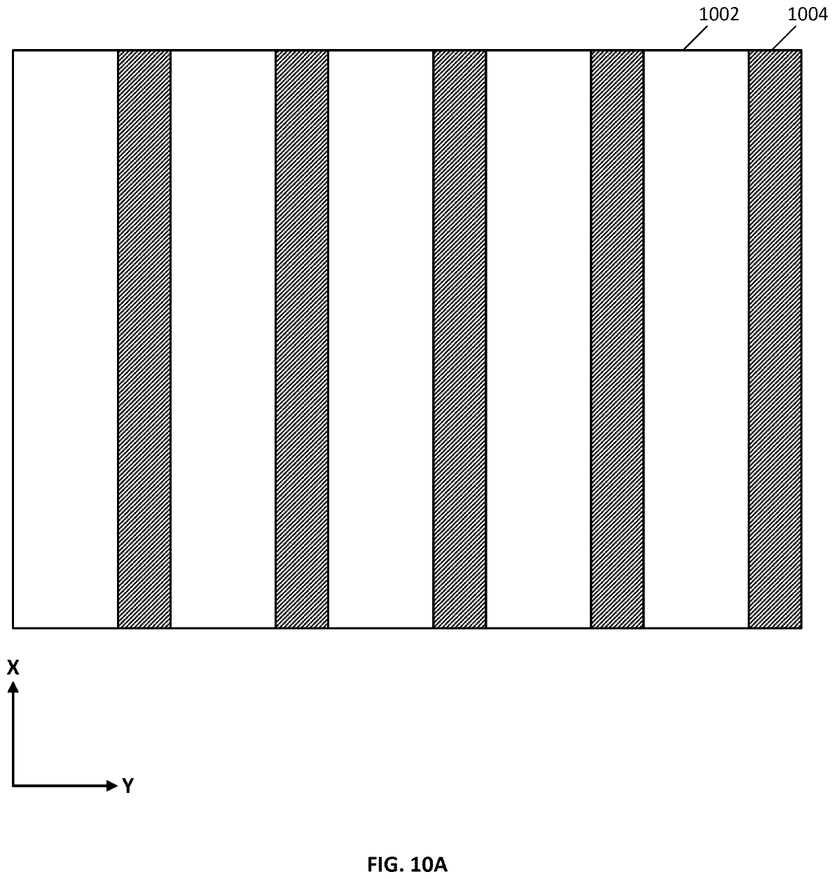

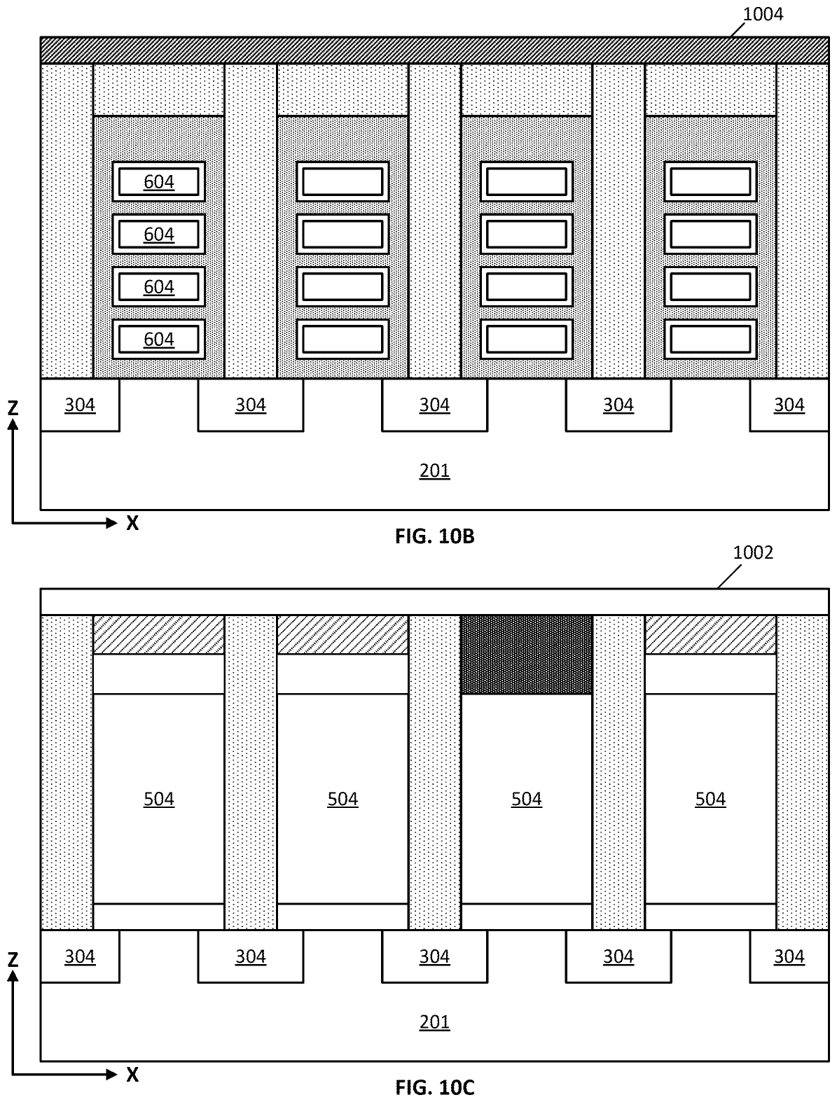

FIGS. 10A-10C depict plan and cross-section views of the structures shown in FIGS. 9A-9C following the self-assembly of various polymer materials, according to some embodiments. A first polymer material 1002 may self-assemble over metal-containing surfaces while a second polymer material may self-assemble over non-metal (e.g., dielectric) surfaces. In some examples, the self-assembly process is performed via vapor or liquid introduction of the polymer materials to at least the exposed top surface of the integrated circuit. According to some embodiments, one or more reactant chemicals are first formed on the exposed materials, which bind to the metal atoms found in both dummy contacts 802 and contacts 902. Then, both first polymer material 1002 and second polymer material 1004 may be introduced to allow first polymer material 1002 to bind to the reactant chemicals on the metal-containing materials and allow second polymer material 1004 to bind to the non-metal areas that run lengthwise in rows along the X-axis (e.g., along dielectric cap layers 602).

According to some embodiments, first polymer material 1002 also runs lengthwise in rows along the X-axis between rows of second polymer material 1004 due to the width difference between cap layers 602 and dielectric walls 702. Recall that dielectric walls 702 are thinner compared to cap layers 602. Accordingly, the assembled first polymer material 1002 is able to bridge across the thinner dielectric walls 702 along the X-axis between adjacent dummy contacts 802 and contacts 902 along the X-axis. FIG. 10B illustrates second polymer material 1004 assembled above the gate trench with nanoribbons 604 while FIG. 10C illustrates first polymer material 1002 assembled above the epi trench with source or drain regions 504. First polymer material 1002 may be poly(methyl methacrylate) (PMMA) while second polymer material 1004 may be polystyrene (PS). In other examples, first polymer material 1002 and second polymer material 1004 may be any two polymer materials that exhibit different assembly properties over metal compared to non-metal surfaces. The self-assembly process allows for the patterning of a material over the gate trench (second polymer material 1004) without needing to align a mask and perform lithography, which yields higher alignment accuracy of second polymer material 1004 over the gate trench.

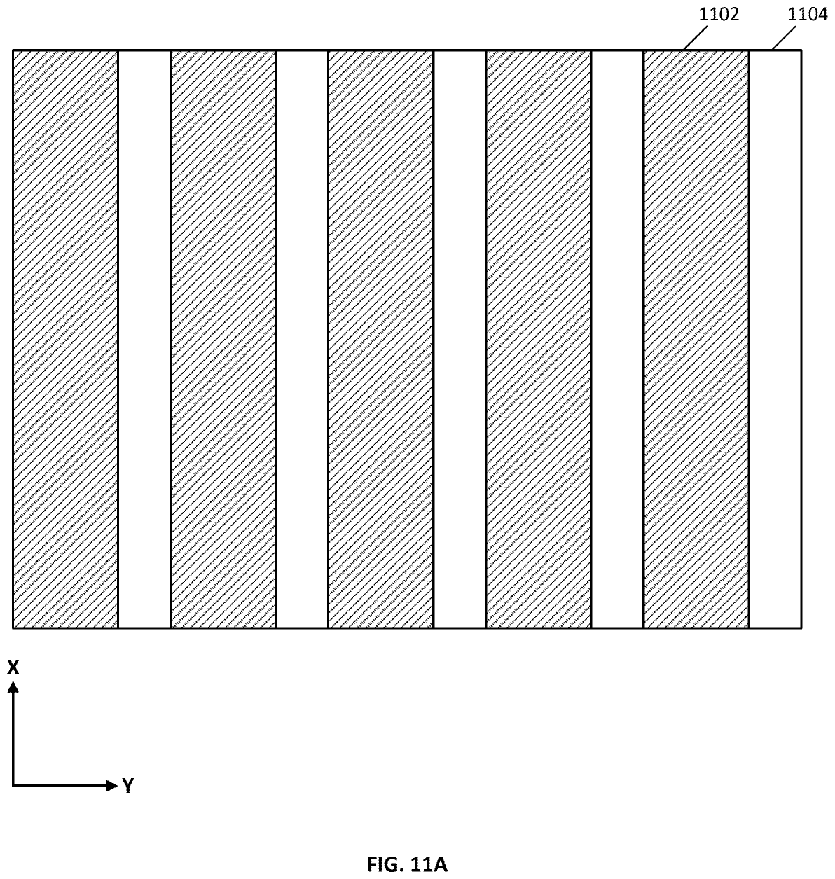

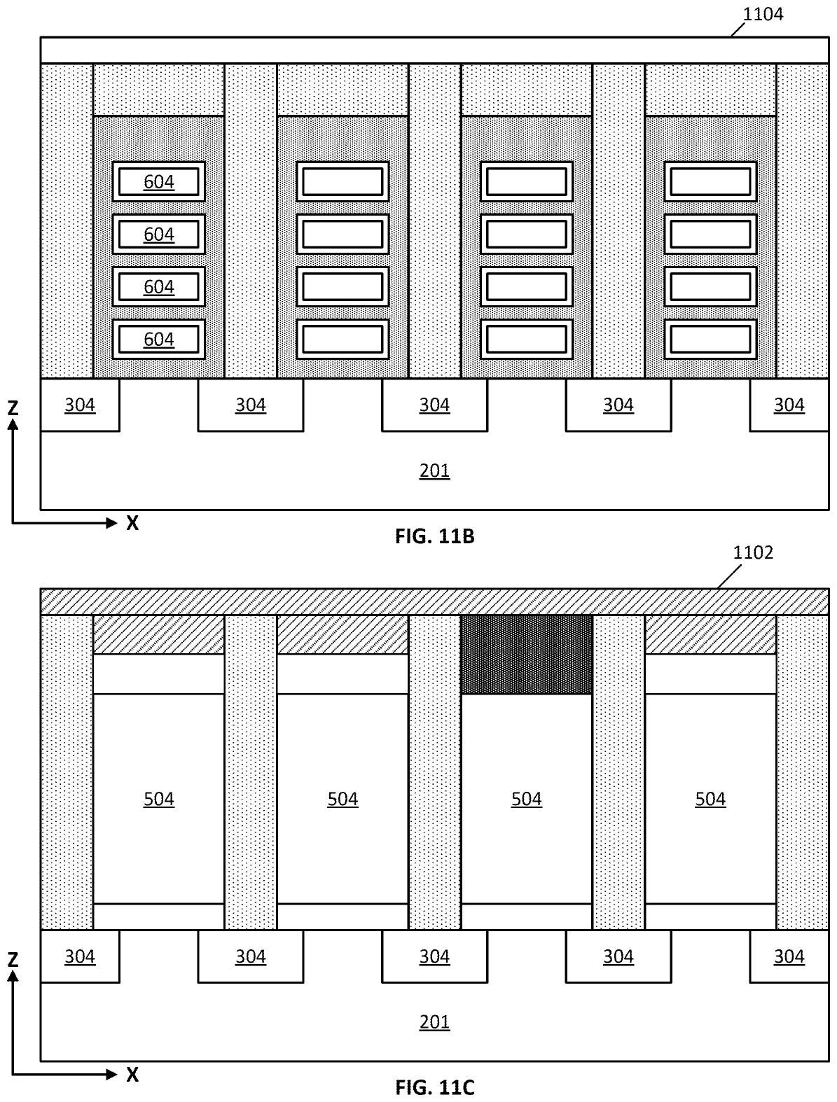

FIGS. 11A-11C depict plan and cross-section views of the structures shown in FIGS. 10A-10C following the replacement of first polymer material 1002 with first masking layer 1102 and the replacement of second polymer material 1004 with second masking layer 1104, according to some embodiments. In more detail, and according to some embodiments, first polymer material 1002 is first selectively removed from around second polymer material 1004. The spaces between second polymer material 1004 may then be filled with first masking layer 1102, which can be any suitable hard mask material, such as titanium nitride. Afterwards, second polymer material 1004 may be removed leaving openings through first masking layer 1102 that are aligned over the gate trenches.

According to some embodiments, some portions of dummy contacts 802 or contacts 902 beneath first masking layer 1102 may be exposed at the bottom edges of first masking layer 1102. To cover these exposed contact materials, another thin layer of material that matches that of first masking layer 1102 may be blanket deposited and etched back to form additional sidewall material to cover the exposed portions of dummy contacts 802 or contacts 902.

The openings through first masking layer 1102 may be filled with second masking layer 1104 to result in the alternating columns of first masking layer 1102 and second masking layer 1104 observed in the plan view of FIG. 11A. According to some embodiments, second masking layer 1104 is any suitable hard mask material that exhibits high etch selectively with first masking layer 1102. In one example, second masking layer 1104 includes silicon oxide. FIG. 11B illustrates second masking layer 1104 formed above the gate trench with nanoribbons 604 while FIG. 11C illustrates first masking layer 1102 assembled above the epi trench with source or drain regions 504.

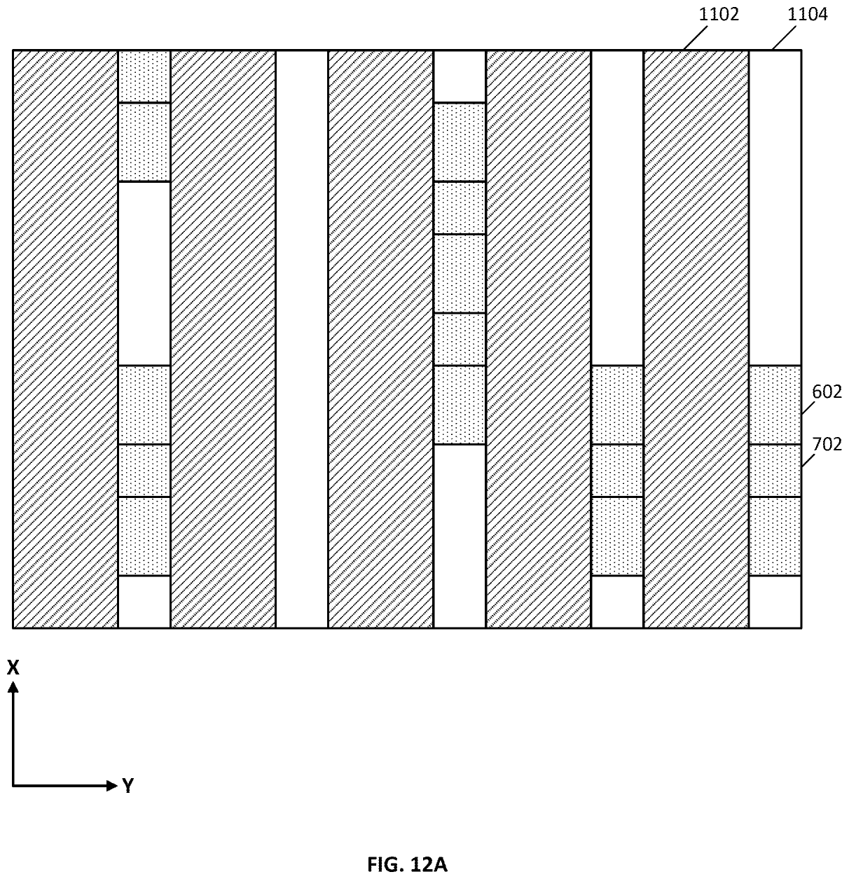

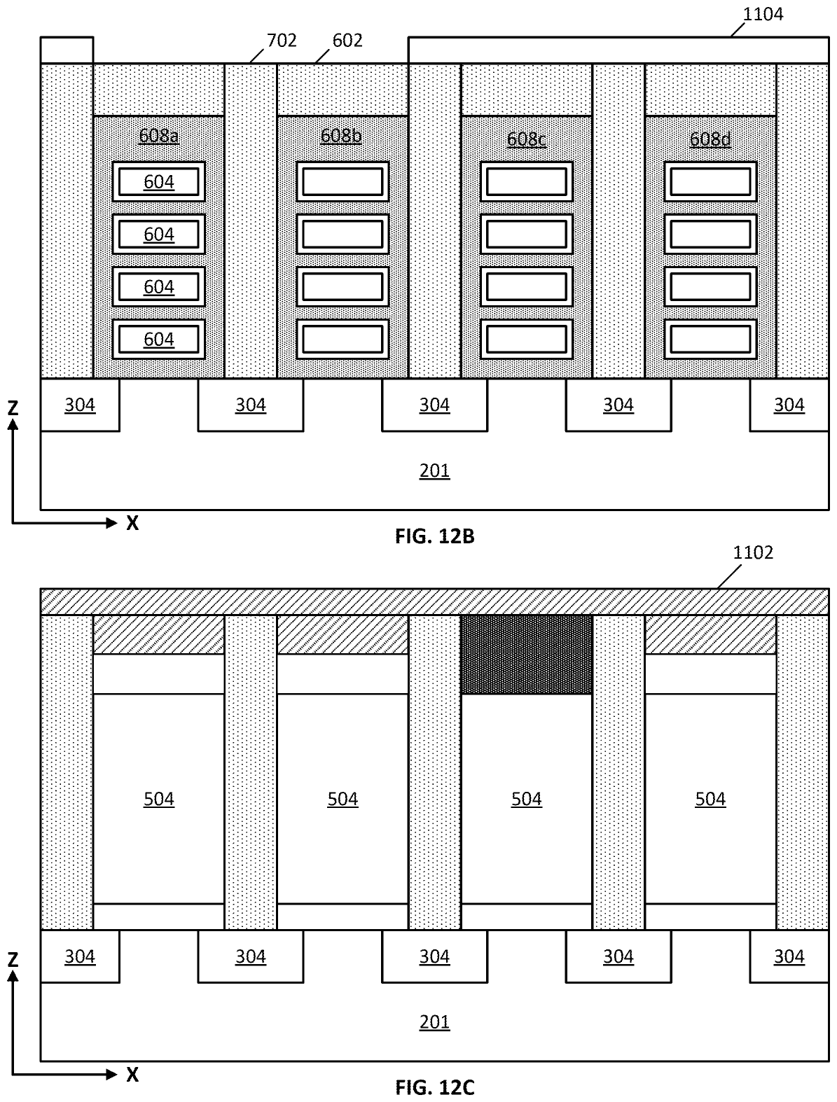

FIGS. 12A-12C depict plan and cross-section views of the structures shown in FIGS. 11A-11C following the removal of portions of second masking layer 1104, according to some embodiments. The removed portions of second masking layer 1104 indicate areas where conductive bridges will be formed to link together any number of underlying adjacent gate structures. Portions of second masking layer 1104 may be removed using any known lithographic masking and etching techniques to expose the underlying portions of cap layers 602 and portions of dielectric walls 702. FIG. 11B illustrates how a removed portion of second masking layer 1104 may be provided over gate electrodes 608a and 608b of two different gate structures. Any other areas of the device may be protected by remaining portions of second masking layer 1104 and by first masking layer 1102. As noted above, the openings through second masking layer 1104 will have a highly accurate alignment in the direction of the Y-axis over the corresponding gate trenches.

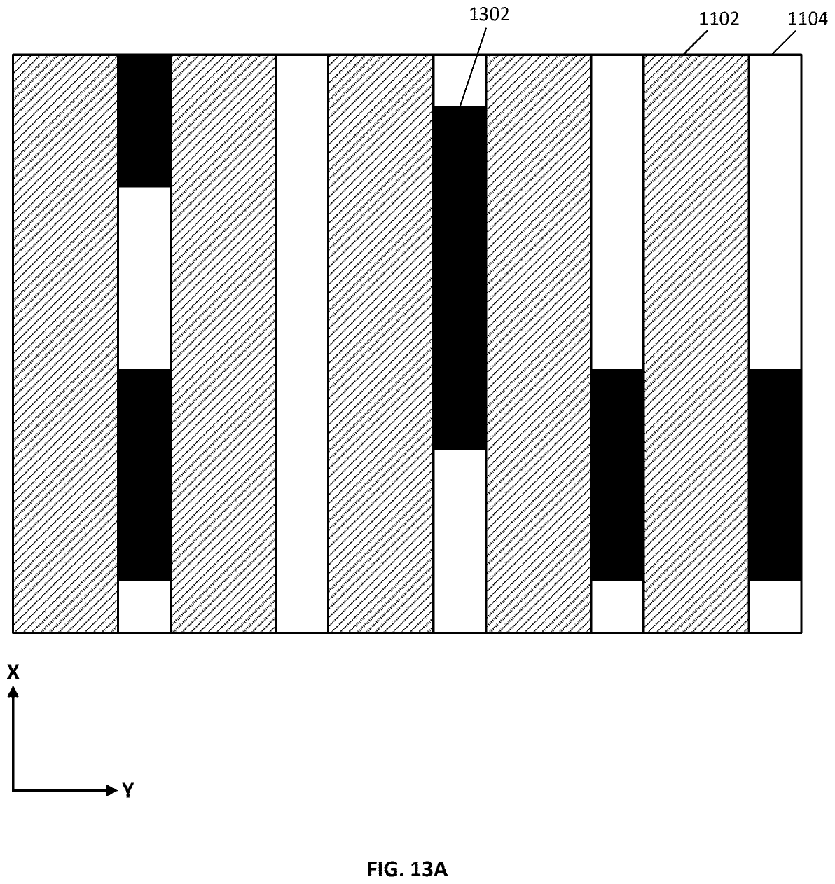

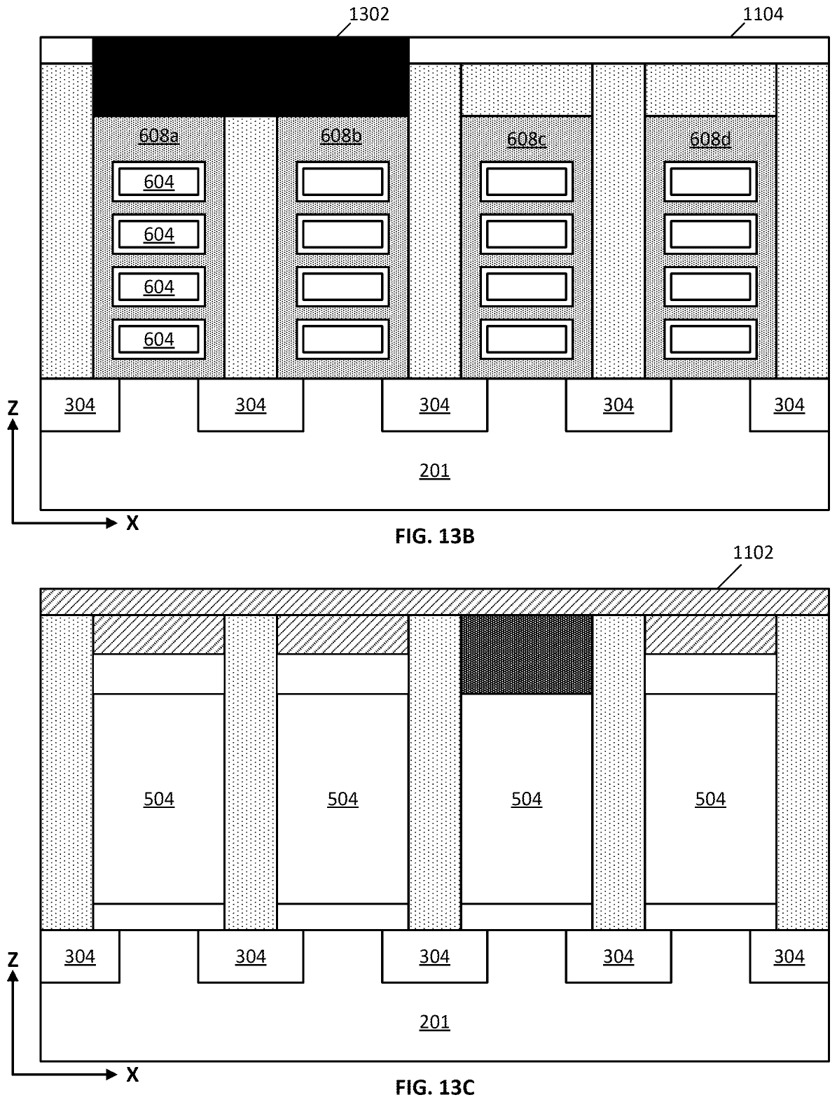

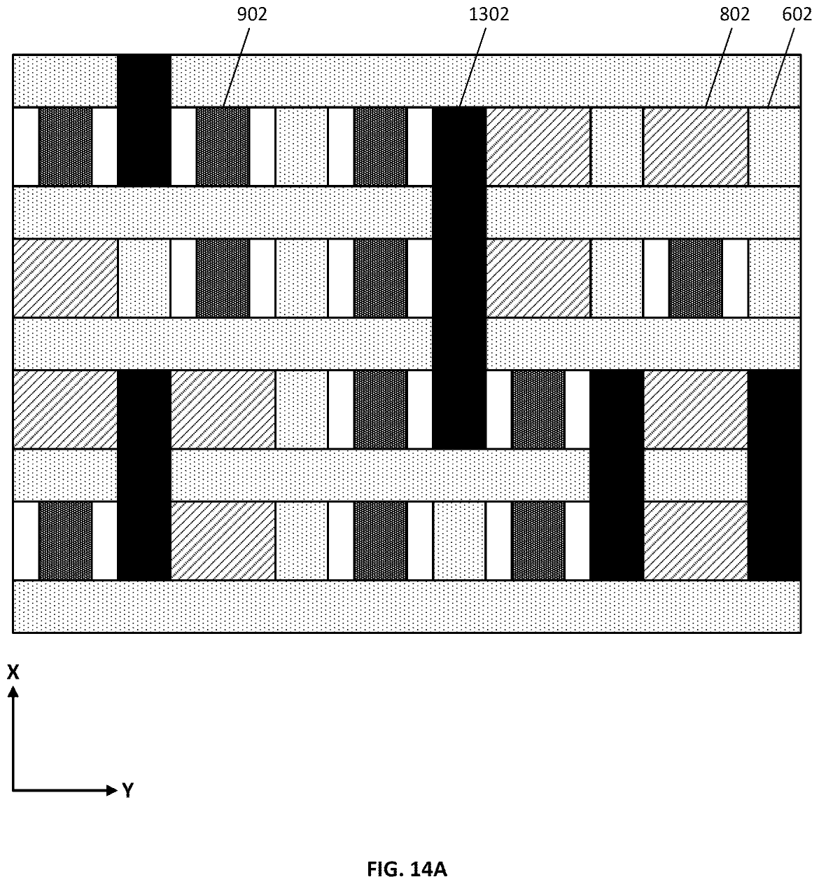

FIGS. 13A-13C depict plan and cross-section views of the structures shown in FIGS. 12A-12C following the removal of the exposed portions of cap layers 602 and portions of dielectric walls 702 and subsequent formation of conductive bridges 1302, according to some embodiments. In examples where cap layers 602 and dielectric walls 702 are the same dielectric material, a single etching process may be used to etch both materials at substantially the same rate. According to some embodiments, both exposed cap layers 602 and dielectric walls 702 are etched at least until top portions of the gate electrodes are exposed, such as the top portions of gate electrodes 608a and 608b as seen in FIG. 13B.

Following the etching of the dielectric materials of both cap layers 602 and dielectric walls 702, the recesses may be filled with a conductive material to form conductive bridges 1302. In some examples, conductive bridges 1302 include a metal such as tungsten, molybdenum or ruthenium. Conductive bridges 1302 may span across any number of semiconductor devices along the X-axis. Due to the self-assembled polymer process to ultimately form second masking layer 1104, conductive bridges 1302 are very accurately aligned within the gate trenches along the Y-axis.

FIGS. 14A-14C depict plan and cross-section views of the structures shown in FIGS. 13A-13C following a polishing process across the integrated circuit, according to some embodiments. A chemical mechanical polishing (CMP) procedure may be used to remove both first masking layer 1102 and second masking layer 1104 to expose both dummy contacts 802 and contacts 902. Further levels of interconnects can be formed to make connections to the various contacts 902. Other interconnects may also be formed to connect to conductive bridges 1302 or to any individual gate structure by forming openings through the above cap layer 602. According to some embodiments, dummy contacts 802 may be removed via a selective isotropic etching process and replaced with a dielectric material, such as silicon oxide or silicon nitride.

It should be understood that the various contacts 902 do not need to remain isolated from one another across the integrated circuit. In some embodiments, a conductive bridge may be formed across one or more dielectric walls 702 to connect neighboring contacts 902, similar to how conductive bridges 1302 connect neighboring gates. In some embodiments, any number of contacts 902 may be connected together via one or more higher level metal interconnects.

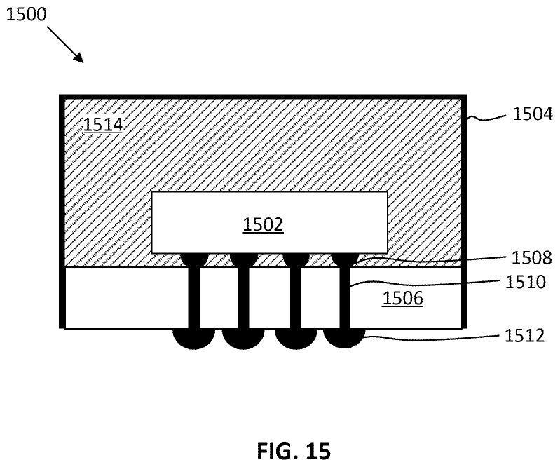

FIG. 15 illustrates an example embodiment of a chip package 1500, in accordance with an embodiment of the present disclosure. As can be seen, chip package 1500 includes one or more dies 1502. One or more dies 1502 may include at least one integrated circuit having semiconductor devices, such as any of the semiconductor devices disclosed herein. One or more dies 1502 may include any other circuitry used to interface with other devices formed on the dies, or other devices connected to chip package 1500, in some example configurations.

As can be further seen, chip package 1500 includes a housing 1504 that is bonded to a package substrate 1506. The housing 1504 may be any standard or proprietary housing, and may provide, for example, electromagnetic shielding and environmental protection for the components of chip package 1500. The one or more dies 1502 may be conductively coupled to a package substrate 1506 using connections 1508, which may be implemented with any number of standard or proprietary connection mechanisms, such as solder bumps, ball grid array (BGA), pins, or wire bonds, to name a few examples. Package substrate 1506 may be any standard or proprietary package substrate, but in some cases includes a dielectric material having conductive pathways (e.g., including conductive vias and lines) extending through the dielectric material between the faces of package substrate 1506, or between different locations on each face. In some embodiments, package substrate 1506 may have a thickness less than 1 millimeter (e.g., between 0.1 millimeters and 0.5 millimeters), although any number of package geometries can be used. Additional conductive contacts 1512 may be disposed at an opposite face of package substrate 1506 for conductively contacting, for instance, a printed circuit board (PCB). One or more vias 1510 extend through a thickness of package substrate 1506 to provide conductive pathways between one or more of connections 1508 to one or more of contacts 1512. Vias 1510 are illustrated as single straight columns through package substrate 1506 for ease of illustration, although other configurations can be used (e.g., damascene, dual damascene, through-silicon via, or an interconnect structure that meanders through the thickness of substrate 1506 to contact one or more intermediate locations therein). In still other embodiments, vias 1510 are fabricated by multiple smaller stacked vias, or are staggered at different locations across package substrate 1506. In the illustrated embodiment, contacts 1512 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1512, to inhibit shorting.

In some embodiments, a mold material 1514 may be disposed around the one or more dies 1502 included within housing 1504 (e.g., between dies 1502 and package substrate 1506 as an underfill material, as well as between dies 1502 and housing 1504 as an overfill material). Although the dimensions and qualities of the mold material 1514 can vary from one embodiment to the next, in some embodiments, a thickness of mold material 1514 is less than 1 millimeter. Example materials that may be used for mold material 1514 include epoxy mold materials, as suitable. In some cases, the mold material 1514 is thermally conductive, in addition to being electrically insulating.

Methodology

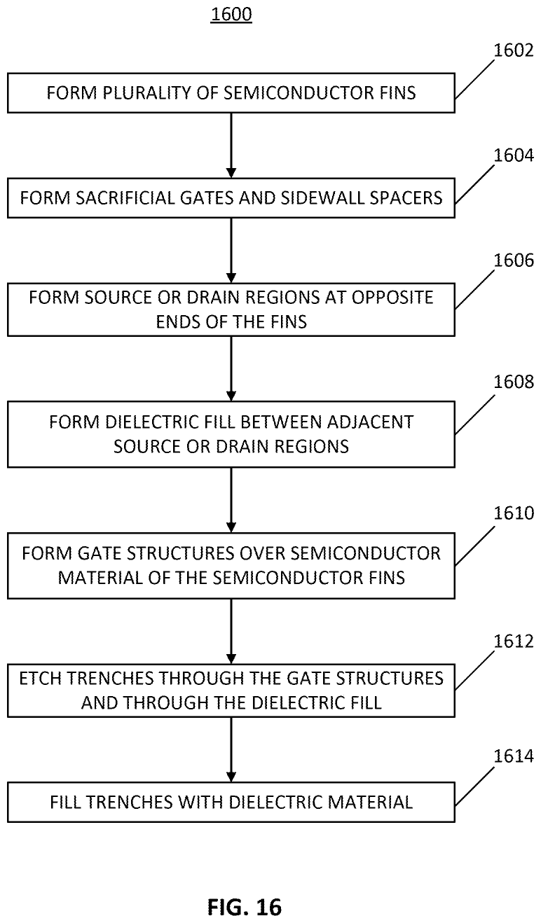

FIG. 16 is a flow chart of a method 1600 for forming at least a portion of an integrated circuit, according to an embodiment. Various operations of method 1600 may be illustrated in FIGS. 2A-14A, 2B-14B, and 2C-14C. However, the correlation of the various operations of method 1600 to the specific components illustrated in the aforementioned figures is not intended to imply any structural and/or use limitations. Rather, the aforementioned figures provide one example embodiment of method 1600. Other operations may be performed before, during, or after any of the operations of method 1600. For example, method 1600 does not explicitly describe various standard processes that are usually performed to form transistor structures. Some of the operations of method 1600 may be performed in a different order than the illustrated order.

Method 1600 begins with operation 1602 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

Method 1600 continues with operation 1604 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 1600 continues with operation 1606 where source or drain regions are formed at opposite ends of the fins. Any exposed portions of the fins not covered by the sacrificial gates or spacer structures may be removed using any anisotropic etching process, such as reactive ion etching (RIE). Once the exposed fins have been removed, the source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon) or PMOS source or drain regions (e.g., epitaxial SiGe).

Method 1600 continues with operation 1608 where a dielectric fill is formed between and over the source or drain regions along a given epi trench. The dielectric fill may be any suitable dielectric material, such as silicon oxide. In some examples, the dielectric fill extends over the source or drain regions up to and planar with a top surface of the spacer structures. One or more conductive contacts may be formed at a later time through the dielectric fill to provide electrical contact to the source or drain regions. The dielectric fill also acts as an electrical insulator between adjacent source or drain regions, although some adjacent source or drain regions may have merged together during their growth.

Method 1600 continues with operation 1610 where gate structures are formed over the semiconductor material of the various semiconductor fins. The sacrificial gates are first removed along with any sacrificial layers within the exposed fins between the spacer structures (in the case of GAA structures). The gate structures may then be formed in place of the sacrificial gates. The gate structures may each include both a gate dielectric and a gate layer. The gate dielectric is first formed over the exposed semiconductor regions between the spacer structures followed by forming the gate layer (or gate electrode) within the remainder of the trench between the spacer structures, according to some embodiments. The gate dielectric may include any number of dielectric layers deposited using a CVD process, such as ALD. The gate layer can include any conductive material, such as a metal, metal alloy, or polysilicon. The gate layer may be deposited using electroplating, electroless plating, CVD, ALD, PECVD, or PVD, to name a few examples.

Method 1600 continues with operation 1612 where trenches are etched through both the gate structures and through the dielectric fill around the source or drain regions. The trenches may extend substantially parallel with one another and lengthwise in the same direction as the length of the fins or nanowires. A single etching process may be used to form all of the trenches through a mask with a grating pattern. A reactive ion etching (RIE) process may be used to cut through the various material layers and form the trenches. Due to the use of a single mask pattern to form the trenches, any alignment registration errors will be consistent across the integrated circuit.

Method 1600 continues with operation 1614 where the trenches are filled with a dielectric material to form parallel dielectric walls through the integrated circuit. The trenches may be filled with any suitable low-K dielectric material, such as silicon nitride. In some embodiments, each pair of semiconductor devices includes a dielectric wall between them. Furthermore, the dielectric walls extend between the gate structures and between the source or drain regions of adjacent devices.

According to some embodiments, each of the gate structures is formed over a semiconductor region of only a single semiconductor device. Each of the gate structures may be constrained over a single semiconductor device along a given gate trench by adjacent dielectric walls. According to some embodiments, one or more conductive bridges may be formed to conductively couple any number of adjacent gate structures together.

Example System

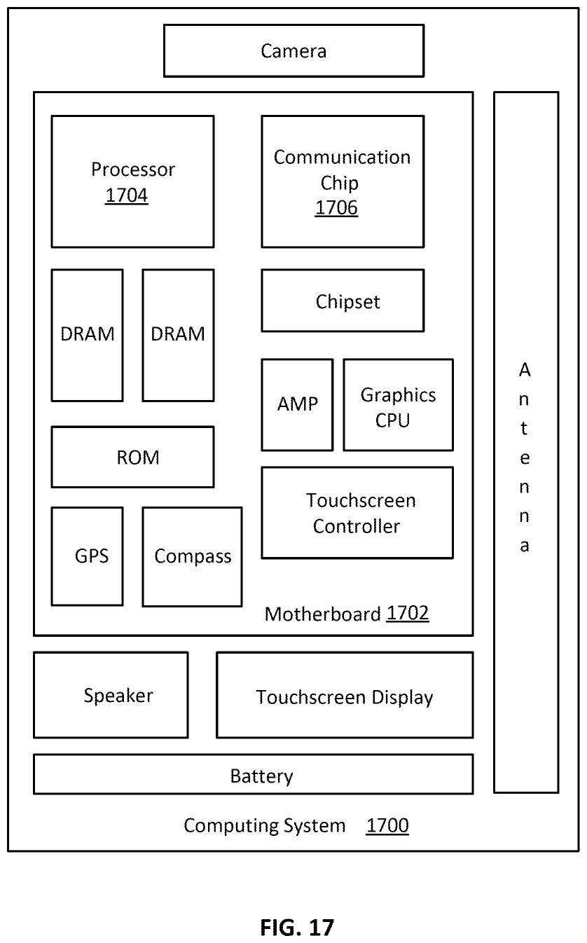

FIG. 17 is an example computing system implemented with one or more of the integrated circuit structures as disclosed herein, in accordance with some embodiments of the present disclosure. As can be seen, the computing system 1700 houses a motherboard 1702. The motherboard 1702 may include a number of components, including, but not limited to, a processor 1704 and at least one communication chip 1706, each of which can be physically and electrically coupled to the motherboard 1702, or otherwise integrated therein. As will be appreciated, the motherboard 1702 may be, for example, any printed circuit board (PCB), whether a main board, a daughterboard mounted on a main board, or the only board of system 1700, etc.

Depending on its applications, computing system 1700 may include one or more other components that may or may not be physically and electrically coupled to the motherboard 1702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1700 may include one or more integrated circuit structures or devices configured in accordance with an example embodiment (e.g., a module including an integrated circuit device on a substrate, the substrate having one or more semiconductor devices with gate cut structures present between each adjacent pair of semiconductor devices, as variously provided herein). In some embodiments, multiple functions can be integrated into one or more chips (e.g., for instance, note that the communication chip 1706 can be part of or otherwise integrated into the processor 1704).

The communication chip 1706 enables wireless communications for the transfer of data to and from the computing system 1700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1700 may include a plurality of communication chips 1706. For instance, a first communication chip 1706 may be dedicated to shorter range wireless communications such as Wi-Fi and Bluetooth and a second communication chip 1706 may be dedicated to longer range wireless communications such as GPS, EDGE, GPRS, CDMA, WiMAX, LTE, Ev-DO, and others.

The processor 1704 of the computing system 1700 includes an integrated circuit die packaged within the processor 1704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1706 also may include an integrated circuit die packaged within the communication chip 1706. In accordance with some such example embodiments, the integrated circuit die of the communication chip includes one or more semiconductor devices as variously described herein. As will be appreciated in light of this disclosure, note that multi-standard wireless capability may be integrated directly into the processor 1704 (e.g., where functionality of any chips 1706 is integrated into processor 1704, rather than having separate communication chips). Further note that processor 1704 may be a chip set having such wireless capability. In short, any number of processor 1704 and/or communication chips 1706 can be used. Likewise, any one chip or chip set can have multiple functions integrated therein.

In various implementations, the computing system 1700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1700 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor body extending lengthwise in a first direction between a first source region and a first drain region, a second semiconductor body extending lengthwise in the first direction between a second source region and a second drain region, a gate structure extending in a second direction different from the first direction and including a first gate layer across the first semiconductor body and a second gate layer across the second semiconductor body, and a dielectric wall extending in the first direction between the first and second source regions, the first and second drain regions, and the first and second gate layers.

Example 2 includes the integrated circuit of Example 1, wherein the dielectric wall comprises silicon and nitrogen, or silicon and oxygen.

Example 3 includes the integrated circuit of Example 1 or 2, wherein the dielectric wall extends in the first direction between additional adjacent source or drain regions of additional semiconductor devices.

Example 4 includes the integrated circuit of any one of Examples 1-3, wherein the first and second semiconductor bodies are semiconductor nanoribbons.

Example 5 includes the integrated circuit of Example 4, wherein the semiconductor nanoribbons comprise germanium, silicon, or a combination thereof.

Example 6 includes the integrated circuit of any one of Examples 1-5, further comprising a conductive layer over a top surface of the dielectric wall, such that the conductive layer contacts the first gate layer on a first side of the dielectric wall and contacts the second gate layer on an opposite second side of the dielectric wall.

Example 7 includes the integrated circuit of any one of Examples 1-6, further comprising spacer structures on sidewalls of each of the first and second gate layers, wherein a dielectric material of the spacer structures is a same dielectric material as the dielectric wall.

Example 8 includes the integrated circuit of any one of Examples 1-7, wherein the dielectric wall is a first dielectric wall, and there is substantially equal spacing in the second direction between the first dielectric wall and a second dielectric wall to a first side of the first dielectric wall, and in the second direction between the first dielectric wall and a third dielectric wall to a second side of the first dielectric wall.

Example 9 includes the integrated circuit of any one of Examples 1-8, wherein the first direction is orthogonal to the second direction.

Example 10 is a printed circuit board comprising the integrated circuit of any one of Examples 1-9.

Example 11 is an electronic device that includes a chip package comprising one or more dies. At least one of the one or more dies includes a plurality of semiconductor devices having one or more semiconductor bodies extending lengthwise in a first direction between corresponding source or drain regions, a plurality of gate layers with each gate layer of the plurality of gate layers extending in a second direction different from the first direction across the one or more semiconductor bodies of a given semiconductor device of the plurality of semiconductor devices, and a plurality of dielectric walls extending lengthwise in the first direction, such that each of the plurality of dielectric walls extends in the first direction between multiple pairs of adjacent semiconductor devices.

Example 12 includes the electronic device of Example 11, wherein the plurality of dielectric walls comprises silicon and nitrogen, or silicon and oxygen.

Example 13 includes the electronic device of Example 11 or 12, wherein the plurality of dielectric walls extend in the first direction between adjacent source or drain regions of the multiple pairs of adjacent semiconductor devices.

Example 14 includes the electronic device of any one of Examples 11-13, wherein the semiconductor bodies each comprise a plurality of semiconductor nanoribbons.

Example 15 includes the electronic device of Example 14, wherein the plurality of semiconductor nanoribbons comprise germanium, silicon, or a combination thereof.

Example 16 includes the electronic device of any one of Examples 11-15, further comprising a conductive layer over a top surface of a given one of the dielectric walls, such that the conductive layer contacts a first gate layer on a first side of the given dielectric wall and contacts a second gate layer on an opposite second side of the given dielectric wall.

Example 17 includes the electronic device of any one of Examples 11-16, further comprising spacer structures on sidewalls of each of the plurality of gate layers, wherein a dielectric material of the spacer structures is a same dielectric material as the plurality of dielectric walls.

Example 18 includes the electronic device of any one of Examples 11-17, wherein the plurality of dielectric walls have a substantially equal spacing in the second direction between adjacent dielectric walls.

Example 19 includes the electronic device of any one of Examples 11-18, wherein the first direction is orthogonal to the second direction.

Example 20 includes the electronic device of any one of Examples 11-19, further comprising a printed circuit board, wherein the chip package is coupled to the printed circuit board.

Example 21 is a method of forming an integrated circuit. The method includes forming a plurality of fins comprising semiconductor material extending above a top surface of a dielectric layer, the plurality of fins each extending lengthwise in a first direction; forming source or drain regions at opposite ends of the semiconductor material of each of the plurality of fins in the first direction; forming a dielectric fill between adjacent source or drain regions; forming strips of gate layers over the semiconductor material of the plurality of fins, the strips of gate layers extending lengthwise in a second direction different from the first direction; etching trenches at least through the strips of gate layers and through the dielectric fill, the trenches extending lengthwise in the second direction; and filling the trenches with a dielectric material.

Example 22 includes the method of Example 21, wherein etching trenches comprises forming a trench through each strip of gate layers between adjacent pairs of fins using a single etching process.

Example 23 includes the method of Example 21 or 22, wherein the semiconductor material comprises first semiconductor layers alternating with second semiconductor layers and the method further comprises removing the second semiconductor layers to form nanoribbons from the first semiconductor layers extending lengthwise in the first direction.

Example 24 includes the method of any one of Examples 21-23, further including forming a dielectric cap layer over the strips of gate layers; forming one or more conductive contacts over corresponding one or more source or drain regions; forming one or more plugs over corresponding one or more other source or drain regions; assembling a first polymer material on the dielectric cap layer; and assembling a second polymer material on the one or more conductive contacts and the one or more plugs.

Example 25 includes the method of Example 24, wherein the second polymer material extends across the trenches with the dielectric material.

Example 26 includes the method of Example 24 or 25, further including replacing the first polymer material with a dielectric masking material; lithographically patterning the dielectric masking material to from openings above the dielectric cap layer; removing the exposed dielectric cap layer within the openings; and forming conductive bridges within the openings.

Example 27 includes the method of any one of Examples 21-26, wherein the second direction is orthogonal to the first direction.

Example 28 is an integrated circuit that includes a first semiconductor body extending in a first direction from a first side of a first source or drain region, a second semiconductor body extending in the first direction from a second side of the first source or drain region, a third semiconductor body extending in the first direction from a first side of a second source or drain region, a fourth semiconductor body extending in the first direction from a second side of the second source or drain region, a first gate structure extending across the first semiconductor body in a second direction different from the first direction, a second gate structure extending across the second semiconductor body in the second direction, a third gate structure extending across the third semiconductor body in the second direction, a fourth gate structure extending across the fourth semiconductor body in the second direction, and a dielectric wall extending in the first direction between the first gate structure and the third gate structure, between the first source or drain region and the second source or drain region, and between the second gate structure and the fourth gate structure.

Example 29 includes the integrated circuit of Example 28, wherein the first semiconductor body, second semiconductor body, third semiconductor body, and the fourth semiconductor body each comprises a plurality of semiconductor nanoribbons.

Example 30 includes the integrated circuit of Example 28 or 29, wherein the first gate structure extends colinear with the third gate structure in the second direction, and the second gate structure extends colinear with the fourth gate structure in the second direction.

Example 31 includes the integrated circuit of any one of Examples 28-30, further comprising a gate dielectric layer around the first, second, third, and fourth semiconductor bodies.

Example 32 includes the integrated circuit of Example 31, wherein the gate dielectric layer is not present on sidewalls of the dielectric wall as it extends between the first gate structure and the third gate structure and between the second gate structure and the fourth gate structure.

Example 33 includes the integrated circuit of any one of Examples 28-32, further comprising a conductive layer over a top surface of the dielectric wall between the first gate structure and the third gate structure, such that the conductive layer contacts both a gate layer of the first gate structure and a gate layer of the second gate structure.

Example 34 includes the integrated circuit of Example 33, further comprising sidewall spacers along sidewalls of the first gate structure and the third gate structure, wherein the conductive layer is aligned between the sidewall spacers.

Example 35 is a printed circuit board comprising the integrated circuit of any one of Examples 28-34.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor body extending lengthwise in a first direction between a first source region and a first drain region;
a second semiconductor body extending lengthwise in the first direction between a second source region and a second drain region;
a gate structure extending in a second direction different from the first direction, the gate structure including a first gate layer across the first semiconductor body and a second gate layer across the second semiconductor body; and
a dielectric wall extending in the first direction between the first and second source regions, the first and second drain regions, and the first and second gate layers.

2. The integrated circuit of claim 1, wherein the dielectric wall comprises silicon and nitrogen, or silicon and oxygen.

3. The integrated circuit of claim 1, wherein the dielectric wall extends in the first direction between additional adjacent source or drain regions of additional semiconductor devices.

4. The integrated circuit of claim 1, further comprising a conductive layer over a top surface of the dielectric wall, such that the conductive layer contacts the first gate layer on a first side of the dielectric wall and contacts the second gate layer on an opposite second side of the dielectric wall.

5. The integrated circuit of claim 1, further comprising spacer structures on sidewalls of each of the first and second gate layers, wherein a dielectric material of the spacer structures is a same dielectric material as the dielectric wall.

6. The integrated circuit of claim 1, wherein the dielectric wall is a first dielectric wall, and there is substantially equal spacing in the second direction between the first dielectric wall and a second dielectric wall to a first side of the first dielectric wall, and in the second direction between the first dielectric wall and a third dielectric wall to a second side of the first dielectric wall.

7. A printed circuit board comprising the integrated circuit of claim 1.

8. A method of forming an integrated circuit, comprising:
forming a plurality of fins comprising semiconductor material extending above a top surface of a dielectric layer, the plurality of fins each extending lengthwise in a first direction;
forming source or drain regions at opposite ends of the semiconductor material of each of the plurality of fins in the first direction;
forming a dielectric fill between adjacent source or drain regions;
forming strips of gate layers over the semiconductor material of the plurality of fins, the strips of gate layers extending lengthwise in a second direction different from the first direction;
etching trenches at least through the strips of gate layers and through the dielectric fill, the trenches extending lengthwise in the second direction; and
filling the trenches with a dielectric material.

9. The method of claim 8, wherein etching trenches comprises forming a trench through each strip of gate layers between adjacent pairs of fins using a single etching process.

10. The method of claim 8, wherein the semiconductor material comprises first semiconductor layers alternating with second semiconductor layers and the method further comprises removing the second semiconductor layers to form nanoribbons from the first semiconductor layers extending lengthwise in the first direction.

11. The method of claim 8, further comprising:
forming a dielectric cap layer over the strips of gate layers;
forming one or more conductive contacts over corresponding one or more source or drain regions;
forming one or more plugs over corresponding one or more other source or drain regions;
assembling a first polymer material on the dielectric cap layer; and
assembling a second polymer material on the one or more conductive contacts and the one or more plugs.

12. The method of claim 11, wherein the second polymer material extends across the trenches with the dielectric material.

13. The method of claim 11, further comprising:
replacing the first polymer material with a dielectric masking material;
lithographically patterning the dielectric masking material to from openings above the dielectric cap layer;
removing the exposed dielectric cap layer within the openings; and
forming conductive bridges within the openings.

14. An integrated circuit comprising:
a first semiconductor body extending in a first direction from a first side of a first source or drain region;
a second semiconductor body extending in the first direction from a second side of the first source or drain region;
a third semiconductor body extending in the first direction from a first side of a second source or drain region;
a fourth semiconductor body extending in the first direction from a second side of the second source or drain region;
a first gate structure extending across the first semiconductor body in a second direction different from the first direction;
a second gate structure extending across the second semiconductor body in the second direction;
a third gate structure extending across the third semiconductor body in the second direction;
a fourth gate structure extending across the fourth semiconductor body in the second direction; and
a dielectric wall extending in the first direction between the first gate structure and the third gate structure, between the first source or drain region and the second source or drain region, and between the second gate structure and the fourth gate structure.

15. The integrated circuit of claim 14, wherein the first gate structure extends colinear with the third gate structure in the second direction, and the second gate structure extends colinear with the fourth gate structure in the second direction.

16. The integrated circuit of claim 14, further comprising a gate dielectric layer around the first, second, third, and fourth semiconductor bodies.

17. The integrated circuit of claim 16, wherein the gate dielectric layer is not present on sidewalls of the dielectric wall as it extends between the first gate structure and the third gate structure and between the second gate structure and the fourth gate structure.

18. The integrated circuit of claim 14, further comprising a conductive layer over a top surface of the dielectric wall between the first gate structure and the third gate structure, such that the conductive layer contacts both a gate layer of the first gate structure and a gate layer of the second gate structure.

19. The integrated circuit of claim 18, further comprising sidewall spacers along sidewalls of the first gate structure and the third gate structure, wherein the conductive layer is aligned between the sidewall spacers.

20. A printed circuit board comprising the integrated circuit of claim 14.
